(19) United States
(12) Patent Application Publication
(10) Pub. No.: US 2015/0255159 A1
(43) Pub. Date: Sep. 10, 2015

(54) METHOD FOR CONTROLLING A NON-VOLATILE SEMICONDUCTOR MEMORY, AND SEMICONDUCTOR STORAGE SYSTEM

(71) Applicant: KABUSHIKI KAISHA TOSHIBA, Minato-ku (JP)

(72) Inventor: Yoshiyuki TANAKA, Kanagawa-ken (JP)

(73) Assignee: KABUSHIKI KAISHA TOSHIBA, Minato-ku (JP)

(21) Appl. No.: 14/643,818

(22) Filed: Mar. 10, 2015

Related U.S. Application Data
(63) Continuation of application No. 12/060,630, filed on Apr. 1, 2008, now abandoned.

(30) Foreign Application Priority Data
Apr. 2, 2007 (JP) 2007-096600

(51) Int. Cl. G11C 16/10

(52) U.S. Cl. CPC G11C 16/10

(57) ABSTRACT

A semiconductor storage system includes a first memory region including at least one block constituted from a plurality of memory cells, the memory cell is capable of storing n bits data, the block is a minimum unit which is capable of being independently erased, a second memory region including at least one block constituted from a plurality of memory cells, the memory cell is capable of storing m (m>n: m is integer) bits data, the block is a minimum unit which is capable of being independently erased, and a controller which controls a number of rewrites for the block in the first memory region not to be more than first predetermined number of times, and controls a number of rewrites for the block in the second memory region not to be more than a second predetermined number of times.

### CROSS-REFERENCE TO RELATED APPLICATIONS

This application is a continuation of and claims the benefit of priority under 35 U.S.C. §120 from U.S. Ser. No. 12/060,630, filed Apr. 1, 2008, which claims the benefit of priority from prior Japanese Patent Application No. 2007-096600, filed Apr. 2, 2007; the entire contents of each of which are incorporated herein by reference.

### FIELD OF THE INVENTION

The present invention relates to semiconductor storage systems, more particularly, management of a number of rewrites in a non-volatile semiconductor memory.

### DESCRIPTION OF THE RELATED ART

In recent years, a memory card which contains a NAND type flash memory as an electrically rewritable and highly integrated non-volatile semiconductor memory is developed for electronic equipment, such as a cellular phone, a digital still camera, and so on.

Memory cells of the NAND type flash memory consist of the two-layer MOS transistor structure of having a floating gate formed on the semiconductor substrate through the tunnel insulation layer, and a control gate formed on the floating gate through the gate insulation layer, and a control gate formed on the floating gate through the gate insulation layer. Each memory cell stores non-volatile data by controlling the threshold voltage as the MOS transistor which depends on the amount of electrons injected into the floating gate.

Specifically, each memory cell stores one bit (binary) information (one of states in 2 pieces of threshold distribution: 2 levels cell) by assigning data “1” to the state of the low threshold voltage in which electrons are emitted from the floating gate and assigning data “0” to the state of the high threshold voltage in which electrons are injected into the floating gate. Moreover, in recent years, the multi level cell technology which stores 2 bits information (one of states in 4 pieces of threshold distribution: 4 levels cell) by subdividing a threshold voltage is developed.

In the NAND type flash memory, the memory cell array constituted by arranging a memory cell in the shape of a matrix is divided into the blocks. Each block is an independently erasable minimum unit. Furthermore, the number of rewrites in each block is managed, and is controlled not to exceed the guaranteed number of rewrites.

Since the 2 levels cells can secure sufficient read-out margin even if a threshold distribution is broad, a write-in speed and data retention reliability are sufficiently high. Therefore, the guaranteed number of rewrites is set up with 100,000 times.

On the other hand, since it is required that the 4 levels cell should have a sharp threshold distribution as compared with the 2 levels cells, more fine control is requested for in the writing to a memory cell. Therefore, a write-in speed becomes about ¼ as compared with the 2 levels cells. Moreover, about data retention reliability, since the read-out margin is insufficient as compared with the 2 levels cells, the guaranteed number of rewrites is set up with 10,000 times.

Conventionally, in the inside of a memory card, the above-mentioned 2 kinds of memory cells are used being intermingled, and the 2 levels cell region and the 4 levels cell region can be coexistent with in one memory chip. Specifically, Japanese Patent Application Laid-Open No. 11.345491 discloses the case where a certain memory space is used as the 2 levels cell, and at certain times, is used as the 4 levels cell. In this case, the number of rewrites for the 2 levels cell region is equalized by using the guaranteed number of rewrites for the 4 levels cell.

### SUMMARY

A first aspect in accordance with the present invention provides a semiconductor storage system which includes a first memory region including at least one block constituted from a plurality of memory cells, the memory cell is capable of storing n bits data, the block is a minimum unit which is capable of being independently erased, a second memory region including at least one block constituted from a plurality of memory cells, the memory cell is capable of storing m (m>n: m is integer) bits data, the block is a minimum unit which is capable of being independently erased, and a controller which controls a number of rewrites for the block in the first memory region not to be more than a first predetermined number of times, and controls a number of rewrites for the block in the second memory region not to be more than a second predetermined number of times.

A second aspect in accordance with the present invention provides a semiconductor storage system which includes a first memory region including at least one block constituted from a plurality of memory cells, the memory cell is capable of storing n bits data, the block is a minimum unit which being capable of being independently erased, a second memory region including at least one block constituted from a plurality of memory cells, the memory cell is capable of storing m (m>n: m is integer) bits data, the block is a minimum unit which is capable of being independently erased, a controller exchanging data stored in a first block with data stored in a second block in the first memory region if a difference of the number of rewrites between the first block and the second block reaches a first limit, and exchanging data stored in a third block with data stored in a fourth block in the second memory region if a difference of the number of rewrites between the third block and the fourth block reaches a second limit.

A third aspect in accordance with the present invention provides a method for controlling a non-volatile semiconductor memory which includes controlling a number of rewrites for a block in a first memory region not to be more than a first predetermined number of times, and controlling a number of rewrites for a block in a second memory region not to be more than a second predetermined number of times, wherein the first memory region including at least one block constituted from a plurality of memory cells, the memory cell being capable of storing n bits data, the block is a minimum unit which is capable of being independently erased, wherein the second memory region including at least one block constituted from a plurality of memory cells, the memory cell being capable of storing m (m>n: m is integer) bits data, the block is a minimum unit which is capable of being independently erased.

### BRIEF DESCRIPTION OF THE DRAWINGS

FIG. 1 illustrates a block diagram of a semiconductor storage system in accordance with a first embodiment of the present invention.

FIG. 2 illustrates an equivalent circuit diagram of a memory core of a semiconductor storage system in accordance with a first embodiment of the present invention.

FIG. 3A, 3B illustrates schematic views of a threshold distribution in memory cells of a semiconductor storage system in accordance with a first embodiment of the present invention.

FIG. 4 illustrates a schematic view of a threshold distribution in memory cells of a semiconductor storage system in accordance with a first embodiment of the present invention.

FIG. 5A, 5B illustrates schematic views of a management table for a number of rewrites of a semiconductor storage system in accordance with a first embodiment of the present invention.

FIG. 6 illustrates a flowchart in a write sequence of a semiconductor storage system in accordance with a first embodiment of the present invention.

FIG. 7 illustrates a flowchart in a write sequence of a semiconductor storage system in accordance with a transformational example of a first embodiment of the present invention.

FIG. 8 illustrates a flowchart in a data update sequence of a semiconductor storage system in accordance with a first embodiment of the present invention.

FIG. 9 illustrates a flowchart in a data update sequence of a semiconductor storage system in accordance with a transformational example of a first embodiment of the present invention.

FIG. 10 illustrates a flowchart in an erase sequence of a semiconductor storage system in accordance with a first embodiment of the present invention.

FIG. 11A, 11B illustrates schematic views of a management table for a number of rewrites of a semiconductor storage system in accordance with a first embodiment of the present invention.

FIG. 12 illustrates a schematic view of a management table for a number of rewrites of a semiconductor storage system in accordance with a first embodiment of the present invention.

FIG. 13 illustrates a flowchart in a wear leveling sequence of a semiconductor storage system in accordance with a first embodiment of the present invention.

FIG. 14 illustrates a schematic view of a management table for a number of rewrites of a semiconductor storage system in accordance with a first embodiment of the present invention.

FIG. 15 illustrates a schematic view of a management table for a number of rewrites of a semiconductor storage system in accordance with a transformational example of a first embodiment of the present invention.

FIG. 16 illustrates a flowchart in a wear leveling sequence of a semiconductor storage system in accordance with a transformational example of a first embodiment of the present invention.

FIG. 17 illustrates a block diagram of a semiconductor memory card in accordance with a second embodiment of the present invention.

FIG. 18 illustrates a schematic view of a memory card holder in accordance with a third embodiment of the present invention.

FIG. 19 illustrates a schematic view of a connector device in accordance with a fourth embodiment of the present invention.

FIG. 20 illustrates a schematic view of a connector device in accordance with a fourth embodiment of the present invention.

### DETAILED DESCRIPTION OF THE EXEMPLARY EMBODIMENTS

Hereafter, some embodiments of the present invention is explained with reference to drawings. First, the consideration process which results in the embodiments of the present invention is explained.

Conventionally, regarding the NAND type flash memory in which the 2 levels cell region and 4 levels cell region are intermingled, the usage of having system data, the file management information, etc. which require high-speed writing and high reliability stored, for example, in the 2 levels cell region, and the main file data stored in the 4 levels cell region was taken.

In this case, since the amounts of data, such as system data and file management information is overwhelmingly small compared with the amount of one of a main file data, the 2 levels cell region had managed by 10,000 times which is the guaranteed number of rewrites for the 4 levels cell instead of 100,000 times which is the guaranteed number of rewrites for the 2 levels cells.

On the other hand, the following situations may arise in the NAND type flash memory developed recently which can stores 4 bits information (one of states in 16 pieces of threshold distribution: 16 levels cell) in one memory cell.

The 16 levels cells have remarkably high cost performance as compared with the 2 levels cells which store 1 bit information in one memory cell. However, since it is required that a threshold distribution should be very sharp, as compared with the 2 levels cells or the 4 levels cell, far fine control is needed, and the write-in speed becomes about 1/64 as compared with the 2 levels cells. Moreover, about data retention reliability, slight change of a threshold voltage may cause read-out error.

For example, although the successive photography of a digital still camera, the high-definition recording of a digital camcorder, the music-download with a mobile music player, etc. require a high write-in speed, the above-mentioned 16 levels cells may be unable to satisfy this required performance.

Then, when using systems, such as a memory card which uses the 16 levels cells, the following control method may be effective. That is, an external host system once write data in the 2 levels cell region constituted in the inside of a memory chip at high speed, and thereafter, the data is transmitted to the 16 levels cell region from the 2 levels cell region in the state of a background at time when no access is required by the external host system.

By applying such control method, the compatibility of the improved performance seen from the external host system with the cost cut by using the 16 levels cells is achieved. In order to secure a certain amount of recording time in the digital still camera or a certain amount of photography number in the digital camcorder, the 2 levels cell region which has suitable capacity is required.

Moreover, since it is necessary to store data to the 2 levels cell region each time, as compared with the conventional case where the 2 levels cell region and the 4 levels cell region are intermingled, the amount of data written in the 2 levels cell region will become vast.

Under such conditions, the storage area inside a memory chip cannot be effectively used if the number of rewrites for the 2 levels cell region is managed by the very small guaranteed number of rewrites for the 16 levels cells as usual. Therefore, in order to effectively use two or more storage areas that a storable number of bits may mutually different, it becomes important how the number of rewrites for each region is managed.

With the following embodiments, a memory system including a NAND type flash memory which has the 2 levels cell region and the 16 levels cell region is taken for an example, and a method for controlling a non-volatile semiconductor memory and a semiconductor storage system in accordance with the embodiments of the present invention are explained.

### First Embodiment

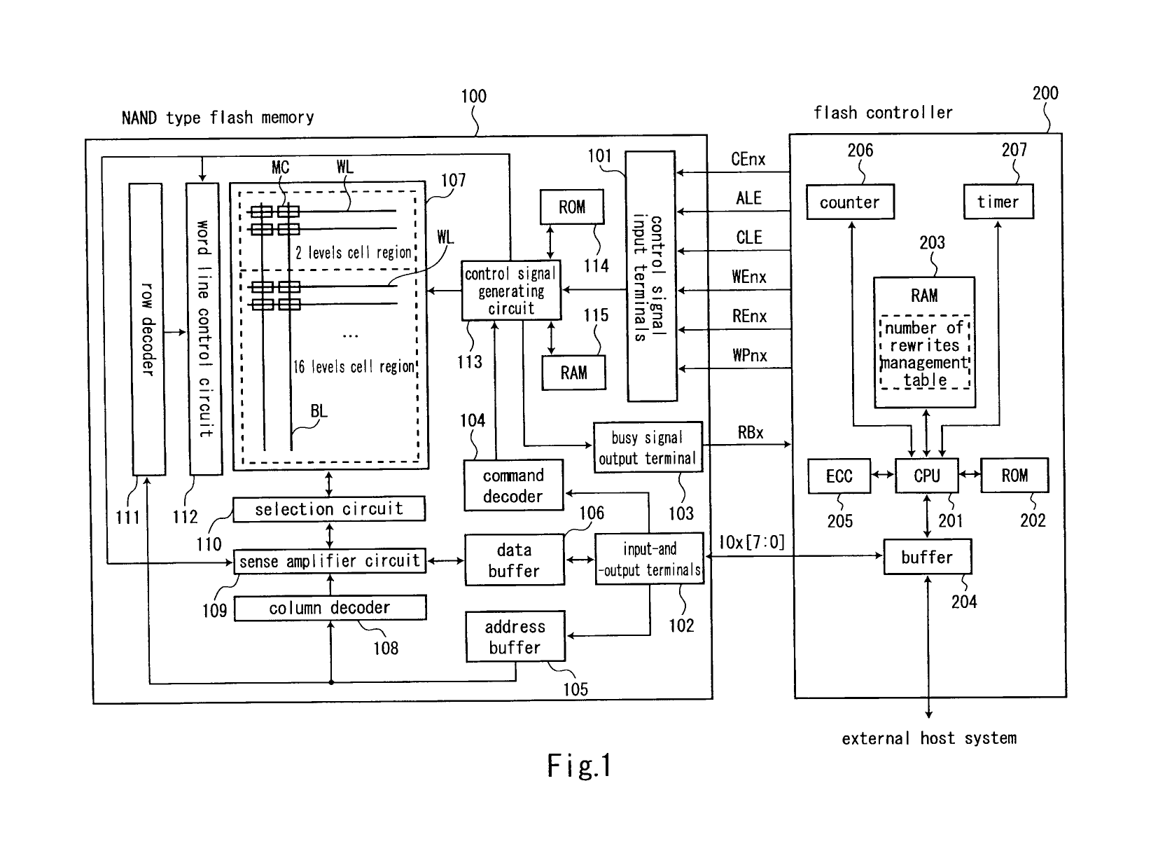

FIG. 1 illustrates a block diagram of a semiconductor storage system (hereafter, called a memory system) in accordance with a first embodiment of the present invention. The memory system includes the NAND type flash memory 100 and the flash controller 200. Although only one NAND type flash memory (one chip) 100 is illustrated in FIG. 1, the memory system concerning the present invention may include plurality, for example, four NAND type flash memories 100 (4 chips).

The flash controller 200 includes the CPU (Central Processing Unit) 201, the ROM (Read Only Memory) 202, the RAM (Random Access Memory) 203, the buffer 204, the ECC (Error Checking and Correcting) circuit 205, the counter 206, and the timer 207. The flash controller 200 accesses the NAND type flash memory 100 according to the request from an external host system, and controls writing of data, reading of data, erasing of data, etc. Moreover, analog circuits, such as an oscillation circuit and a voltage detection circuit (illustration omitted) are integrated in the flash controller 200.

The CPU 201 controls the whole operation of the memory system. When the memory system receives a power supply voltage, CPU 201 reads the farm wear stored in the ROM 202 on the RAM203, and performs predetermined processing.

The ROM 202 stores the farm wear used by the CPU 201, and the RAM 203 is used as work area of the CPU 201. Moreover, a management table for the number of rewrites (mentioned later) is transmitted from the NAND type flash memory 100 to the RAM 203 at the time of receiving the power supply voltage.

The buffer 204 stores a fixed quantity of data temporarily in case the data transmitted from an external host system is written to the NAND type flash memory 100. And the buffer 204 stores a fixed quantity of data temporarily in case the data read from the NAND type flash memory 100 is transmitted to an external host system.

The ECC circuit 205 generates an ECC code based on the write-in data inputted into the flash controller 200 from an external host system and adds it to the write-in data in case of writing data to the NAND type flash memory 100. Moreover, the ECC circuit 205 detects or corrects errors by comparing an ECC code generated based on the read-out data with the ECC code which was added in writing in case of reading from the NAND type flash memory 100.

The ECC circuit 205 may use a coding method as error correction algorithm such as the Humming code, the Reed Solomon (RS) code, or the LDPC (Low Density Parity Check) code, etc.

The counter 206 is used for management of the number of rewrites. In the present embodiment, the counter 206 counts the number of erases for the block BLK. The block BLK is the minimum unit in which data is erased independently. The timer 207 detects that predetermined time has passed after access of an external host system is completed, and notifies the detection result to the CPU 201.

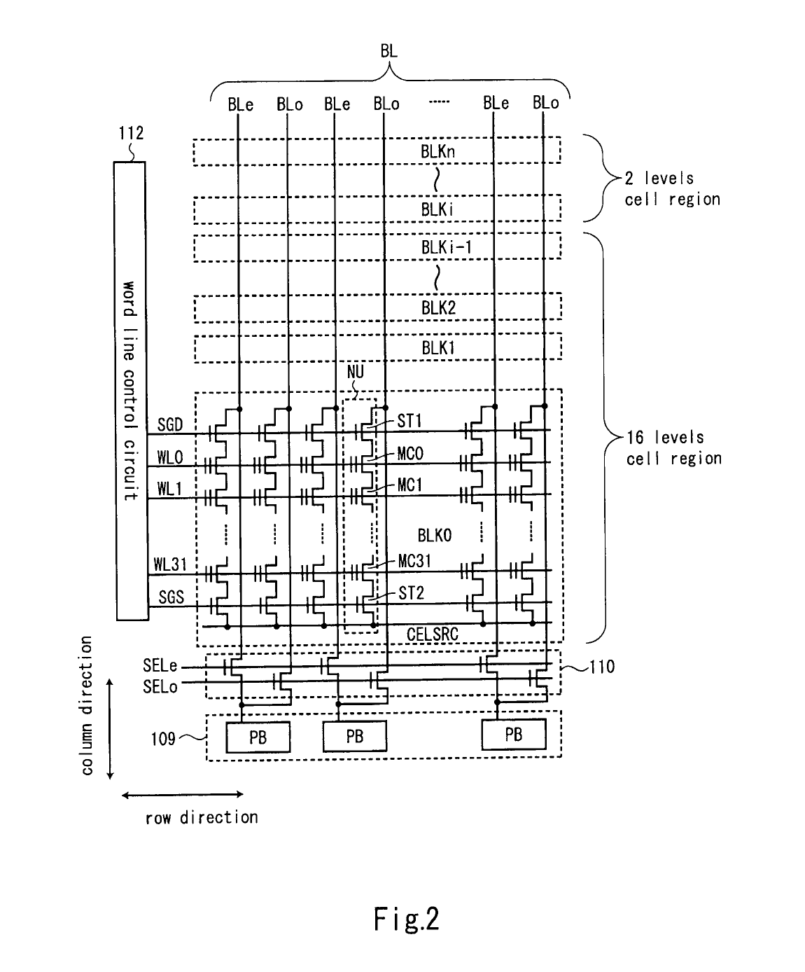

The internal structure of the NAND type flash memory 100 is explained with reference to FIG. 1 and FIG. 2. FIG. 2 illustrates an equivalent circuit diagram of a memory core of a semiconductor storage system in accordance with a first embodiment of the present invention.

The NAND type flash memory 100 includes the control signal input terminals 101, the input-and-output terminals 102, the busy signal output terminal 103, the command decoder 104, the address buffer 105, the data buffer 106, the memory cell array 107, the column decoder 108, the sense amplifier circuit 109, the selection circuit 110, the row decoder 111, the word line control circuit 112, the control signal generating circuit 113, the ROM 114, and the RAM 115.

External control signals, such as the chip enable signal CEnx, the write enable signal WEnx, the read enable signal REnx, the command latch enable signal CLEx, the address latch enable signal ALEx, and the write protect signal WPnx, are inputted into the control signal generating circuit 113 through the control signal input terminal 101 from the flash controller 200.

The commands, an address, and data inputted from the flash controller 200 are transmitted to the command decoder 104, the address buffer 105, and the data buffer 106 through the input-and-output terminals 102 (I/O terminals). Moreover, the status signal RBx which shows whether the NAND type flash memory 100 is in the ready state or in the busy state for write-in, read-out, or erase operation is outputted to the flash controller 200 through the busy signal output terminal 103.

The command decoder 104 decodes the commands inputted through the input-and-output terminals 102, and transmits the decoded results to the control signal generating circuit 113. The address buffer 105 stores an address temporarily inputted through the input-and-output terminals 102, and transmits a column address to the column decoder 108, and transmits a row address to the row decoder 111. The data buffer 106 stores data temporarily inputted through the input-and-output terminals 102, and transmits the data to the sense amplifier circuit 109.

As shown in FIG. 2, the memory cell array 107 is constituted of the plurality of NAND cell units (the NAND strings) NU. The NAND cell unit NU includes the electrically rewritable non-volatile memory cells MC0 to MC31 (hereafter, generally may be called the memory cell MC), the first select gate transistor ST1, and the second select gate transistor ST2 connected in-series.

The memory cell MC consists of, for example, the two-layer MOS transistor structure of having the floating gate formed through the tunnel insulation film on the semiconductor substrate, and the control gate laminated through the gate insulation film on the floating gate. The memory cell MC stores data with non-volatile state by controlling the threshold voltage as a MOS transistor according to the amount of the charge injected into the floating gate.

The one end of the NAND cell unit NU is connected to the bit line BL through the first select gate transistor ST1 and the other end is connected to the common source line CELSRC through the second select gate transistor ST2.

The control gate of the memory cell MC of the same line respectively extends in the direction of a row and commonly connected each other. The commonly connected control gates constitute the word lines WL0 to WL31 (hereafter, generally may be called the word line WL).

Moreover, the control gate of the first select gate transistor ST1 and the second select gate transistor ST2 respectively extend in the direction of a row and commonly connected each other. The commonly connected control gates constitute the select gate lines SGD and SGS.

A set of the NAND cell units NU arranged in the direction of a row constitutes the block BLK defined as the minimum unit in which data is erased independently. Two or more blocks BLK0 to BLKn are arranged in the direction of a column.

As shown in FIG. 2, in the memory cell array 107, i pieces of block BLK0 to BLK(i−1) are used as the 16 levels cell region (second memory region) where one memory cell MC can store 4 bits information, and (n−i+1) pieces of block BLKi to BLKn are used as the 2 levels cell region (first memory region) where one memory cell MC can store 1 bit information.

For example, in the case where a memory system has 8 chips of NAND type flash memory with a capacity of 4 GB, i.e., the capacity of the memory system is 32 GB as a whole, the memory cell array 107 may be constituted so that the 2 levels cell region occupies about the capacity of 100 MB in arbitrary one chip.

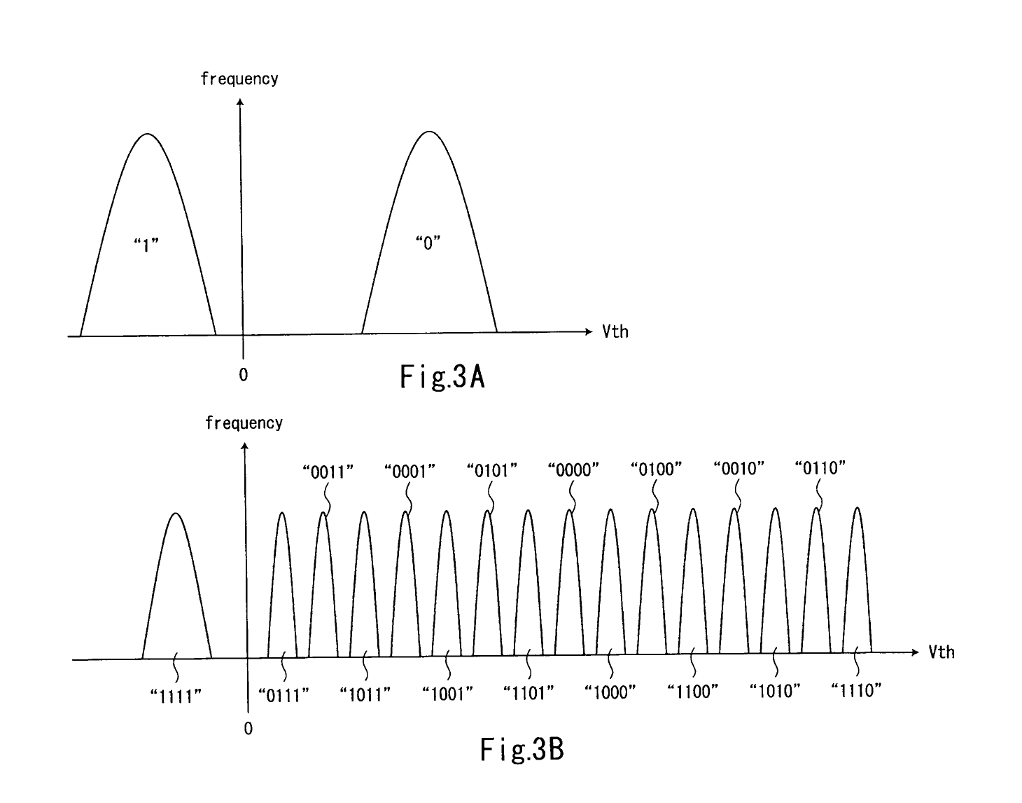

The memory cell MC in the 2 levels cell region can store 1 bit information (one of states in 2 pieces of threshold distribution) by assigning data “0” for the high threshold state where the electrons are injected into the floating gate, and assigning data “1” for the low threshold state where the electrons are emitted from the floating gate, as shown in FIG. 3A.

Since the memory cell MC in the 2 levels cell region can secure sufficient read-out margin even if a threshold distribution is broad, a write-in speed is rather high, and for example, data is written at the speed of 20 MB/sec. Moreover, the memory cell MC in the 2 levels cell region also has sufficient reliability about data retention. Therefore, the guaranteed number of rewrites on the 2 levels cell region (first predetermined number of times) may be set up with 100,000 times.

The blocks BLK which constitute the 2 levels cell region are further divided into two regions. One region (third memory region) is included into the object of the wear leveling (that is, equation of the number of rewrites, mentioned later), and the other region (fourth memory region) is excluded from the object of the wear leveling. The region included into the object of the wear leveling includes the blocks BLK which constitute the buffer region (mentioned later) with which the transmission of write-in data to the 16 levels cell region from the 2 levels cell region is executed. The region excluded from the object of the wear leveling includes the blocks BLK which store important management data, such as the farm wear for the flash controller 200 and others.

The memory cell MC in the 16 levels cell region manages threshold distribution with subdivided state rather than the memory cell MC in the 2 levels cell region, as shown in FIG. 3B. The memory cell MC in the 16 levels cell region store 4 bits information (one of states in 16 pieces of threshold distribution), for example, in order of threshold voltage, data “1111”, data “0111”, data “0011”, data “1011”, data “0001”, data “1001”, data “0101”, data “1101”, data “0000”, data “1000”, data “0100”, data “1100”, data “0010”, data “1010”, data “0110”, and data “1110”.

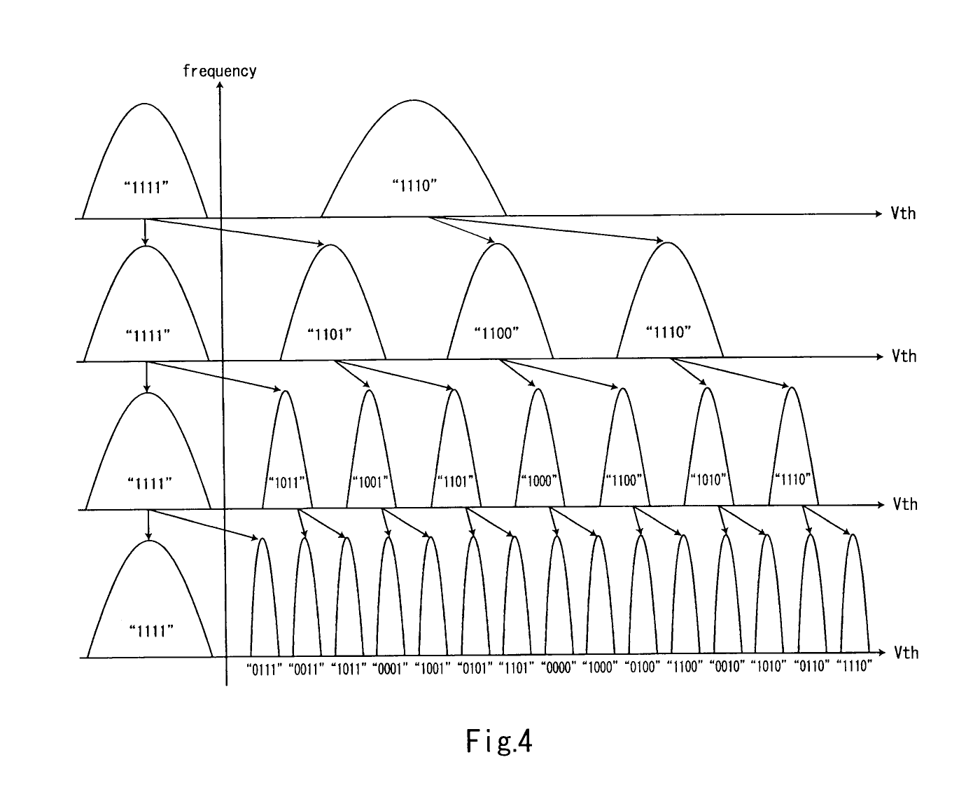

FIG. 4 illustrates an example of a program sequence to form 16 pieces of threshold distribution. FIG. 4 shows a page-by-page programming method. In this programming method, the first page programming forms threshold distributions corresponding data “1111” and data “1110”. The second page programming forms threshold distributions corresponding data “1111”, data “1101”, data “1100”, and data “1110”.

The third page programming forms threshold distributions corresponding data “1111”, data “1011”, data “1001”, data “1101”, data “1000”, data “1100”, data “1010”, and data “1110”. The fourth page programming forms threshold distributions corresponding data “1111”, data “0111”, data “0011”, data “1011”, data “0001”, data “1001”, data “0101”, data “1101”, data “0000”, data “1000”, data “0100”, data “1100”, data “0010”, data “1010”, data “0110”, and data “1110”.

In the present embodiment, the 2 levels cell region may use 2 pieces of threshold distribution selected among multi-value states by fixing part of pages (a pseudo 2 levels cell). Moreover, only using the first page programming may be available for the 2 levels cell region.

Since it is required that the memory cell MC in the 16 levels cell region should have a very sharp threshold distribution, far fine write-in control is needed, and the write-in speed becomes about 1/64 as compared with the 2 levels cells. Moreover, about the reliability for data retention, slight change of a threshold voltage may cause read-out error. Therefore, the guaranteed number of rewrites on the 16 levels cell region (second predetermined number of times) may be set up with 1,000 times.

In addition, the above mentioned guaranteed number of rewrites is the predetermined value which should be statistically determined based on the results of the data retention reliability test of the memory cell MC, and so on. The guaranteed number of rewrites may be set up suitably in consideration of the number of bits which the memory cell MC can store, or a physical characteristic, etc.

The number of blocks which constitutes the buffer region of the 2 levels cell region is preferable to be 33% or less of the sum of the number of blocks which constitutes the buffer region of the 2 levels cell region and the number of blocks which constitutes the 16 levels cell region.

It is because, if the number of blocks which constitutes the buffer region of the 2 levels cell region is 34% or more of the sum of the number of blocks which constitutes the buffer region of the 2 levels cell region and the number of blocks which constitutes the 16 levels cell region, a large storage capacity can be obtained by using the whole blocks which constitutes the memory cell array 107 as the 8 level cells which can store 3 bits information, in comparison of the same number of blocks.

In the present embodiment, once write-in data is transmitted into the buffer region of the 2 levels cell region at high speed, and thereafter, the data is transmitted to the 16 levels cell region from the 2 levels cell region in the state of a background at time when no access is required by the external host system.

Therefore, representing the number of blocks for the buffer region of the 2 levels cell region as A, and the number of blocks for the 16 levels cell region as B, the guaranteed number of rewrites on the 2 levels cell region is preferable to be more than a time (4 B/A). If the guaranteed number of rewrites is less than a time (4 B/A), the blocks BLK which constitute the buffer region of the 2 levels cell region reach the guaranteed number of rewrites before using each block BLK which constitute the 16 levels cell region at least one time.

The column decoder 108 decodes a column address transmitted from the address buffer 105, and transmits the decoded address to the sense amplifier circuit 109. The sense amplifier circuit 109 is arranged at the one end of the bit line BL, and is utilized for writing and reading of data according to a column address inputted from the column decoder 108.

The sense amplifier circuit 109 includes a plurality of page buffers PB, and the page buffer PB is selectively connected to either the even-bit line BLe or the odd-bit line BLo. The even-bit lines BLe are the group which consists of the even-numbered bit lines BL counted from an end of the bit line BL in the block BLK. The odd-bit lines BLo are the group which consists of the odd-numbered bit lines BL counted from an end of the bit line BL in the block BLK.

In the block BLK, a set of the memory cells MC selected by one word line WL and even-bit lines BLe constitute 1 page which is the unit of simultaneously writing and reading, and a set of the memory cells MC selected by the one word line WL and odd-bit lines BLo constitute the other 1 page.

The selection circuit 110 connects one of two groups of the bit lines BLe and BLo with the sense amplifier circuit 109 as the “selected” bit lines. The selection circuit 110 does not connect another one of two groups of the bit lines BLe and BLo with the sense amplifier circuit 109 as the “non-selected” bit lines. Moreover, at the time of data reading, the coupling noise between the bit lines BL is reduced by grounding the non-selected bit lines BL.

The row decoder 111 decodes a row address transmitted from the address buffer 105, and transmits the decoded address to the word line control circuit 112. The word line control circuit 112 is arranged at the one end of the word line WL, and selectively drives the word lines WL, the select gate line SGS, and the select gate line SGD according to a row address inputted from the row decoder 111.

The control signal generating circuit 113 is an internal control circuit of the NAND type flash memory 100, and a part or the entire control program is stored in the ROM 114 and the RAM 115. When the memory system receives power supply voltage, a part or the entire control program is transmitted to the RAM 115. The control signal generating circuit 113 controls various operation, such as write, read, and erase operation according to the command inputted from the command decoder 104 based on the control program transmitted to the RAM 115.

The method for managing the number of rewrites in the memory system which has above-mentioned structures is explained below.

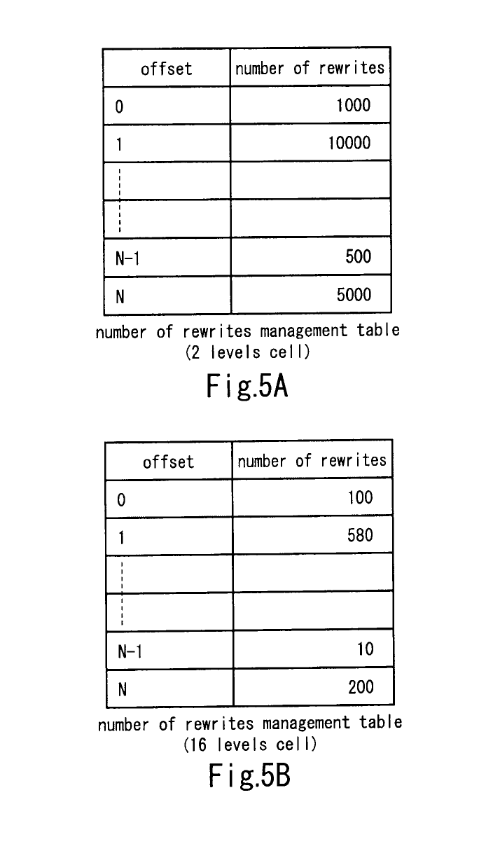

FIG. 5A illustrates schematic views of a management table for the number of rewrites in each block of the 2 levels cell region of a semiconductor storage system in accordance with a first embodiment of the present invention. FIG. 5B illustrates schematic views of a management table for the number of rewrites in each block of the 16 levels cell region of a semiconductor storage system in accordance with a first embodiment of the present invention.

The offset in FIG. 5A means the block address from the head of the memory cell array 107, i.e., from the block BLK0. Moreover, the offset in FIG. 5B is equivalent to the block address counted from the boundary of the 2 levels cell region and the 16 levels cell region, i.e., from the block BLKi.

The number of rewrites management table is stored with non-volatile state in the memory cell array 107 of the NAND type flash memory 100, and is transmitted to the RAM 203 in the flash controller 200 when the memory system receives the power supply voltage.

Since the number of rewrites management table is important data, it is stored in the 2 levels cell region where the reliability of data retention is relatively high. In addition, the number of rewrites management table is stored in the region excluded from the object of the wear leveling in the 2 levels cell region.

In the present embodiment, the value which is contained to the number of rewrites management table as the number of rewrites for each block BLK is defined as the number of erases for each block BLK. Namely, whenever each block BLK is erased, the number of rewrites for the block BLK is incremented by the counter 206, and the field of the number of rewrites management table stored on the RAM 203 and the field of the number of rewrites management table which is stored with non-volatile state in the memory cell array 107 are updated.

For example, FIG. 5A shows the number of rewrites management table for the 2 levels cell region when the block BLK of offset=“0” has erased 1,000 times, the block BLK of offset=“1” has erased 10,000 times, the block BLK of offset=“N” has erased 500 times, and the block BLK of offset=“N−1” has erased 5,000 times.

Moreover, FIG. 5B shows the number of rewrites management table for the 16 levels cell region when the block BLK of offset=“0” has erased 100 times, the block BLK of offset=“1” has erased 580 times, the block BLK of offset=“N−1” has erased 10 times, and the block BLK of offset=“N” has erased 200 times.

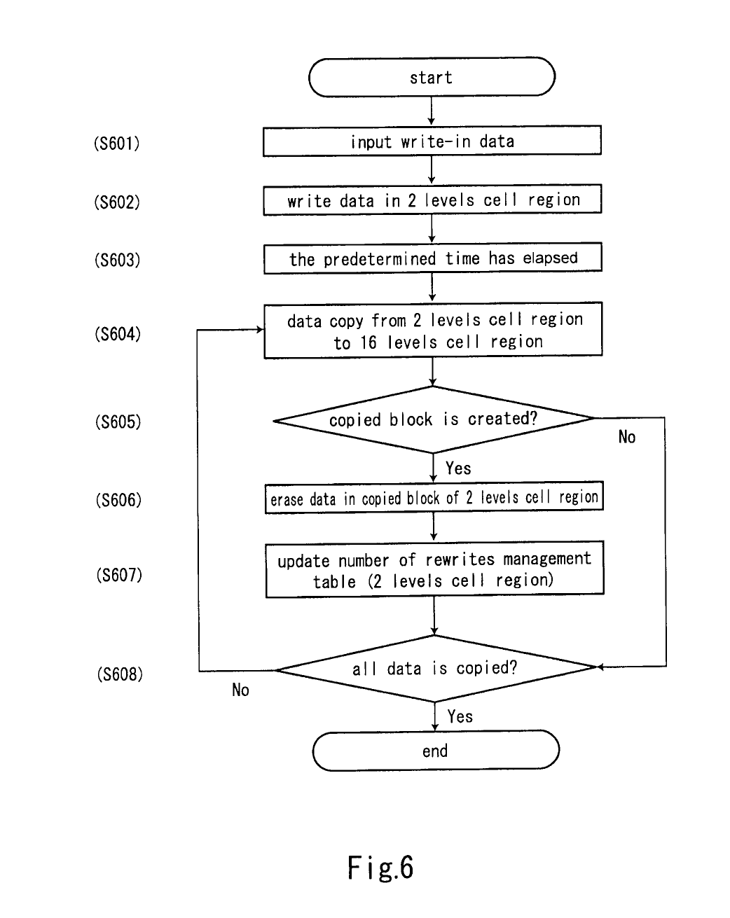

Hereafter, the operation of the memory system when the contents of the number of rewrites management table are updated is explained concretely. First, the data write sequence at the time of writing data into the memory system from an external host system is explained with reference to FIG. 6. FIG. 6 illustrates a flowchart in a write sequence of a semiconductor storage system in accordance with a first embodiment of the present invention.

In the memory system in accordance with the present embodiment, once write-in data is written in the buffer region which consists of a plurality of blocks BLK inside the 2 levels cell region of the memory cell array 107 at relatively high speed, and thereafter, the data is transmitted to the 16 levels cell region from the 2 levels cell region (the buffer region) in the state of a background at time when no access is required by the external host system. Hereafter, detailed operation is explained.

The write-in data inputted into the memory system from the external host system is temporarily stored in the buffer 204 of the flash controller 200. The ECC code, such as, the Humming code, is generated by the ECC circuit 205, and the data and ECC parity bits are transmitted to the data buffer 106 through the input-and-output terminals 102.

Moreover, the flash controller 200 manages which address area inside the memory cell array 107 is the 2 levels cell region or the 16 levels cell region. The address of the 2 levels cell region in the memory cell array 107 is assigned first to the write-in data inputted into the memory system, and this address is transmitted to the address buffer 105 through the input-and-output terminals 102 (S601).

The write-in data which has transmitted to the data buffer 106 is loaded to the sense amplifier circuit 109, and is written in the 2 levels cell region inside the memory cell array 107 according to the address decoded by the column decoder 108 and the row decoder 111 (S602).

If the timer 207 inside the flash controller 200 detects that predetermined time has elapsed after access to the memory system from the external host system is completed, the timer 207 notify the information which represents that the predetermined time elapsed to the CPU 201. The predetermined time may be suitably set up in consideration of the access frequency from an external host system etc. (S603).

When the CPU 201 receives the notification from the timer 207, the data copy operation to the 16 levels cell region from the 2 levels cell region is started. The write-in data stored in the 2 levels cell region of the memory cell array 107 is read to the sense amplifier circuit 109, and the data is once transmitted to the RAM 203 inside the flash controller 200 through the data buffer 106 and the input-and-output terminals 102. If the read-out data contains an error, error correction processing is executed by the ECC circuit 205.

In addition, the read-out operation from the 2 levels cell region may be performed in order of the address in the 2 levels cell region, and may be performed in the order by which data was written in the 2 levels cell region. Moreover, the amount of data transmitted to the RAM 203 may be suitably set up in consideration of the capacity of the RAM 203 etc.

The data read-out from the 2 levels cell region on the RAM 203 is again inputted into the NAND type flash memory 100. The address of the 16 levels cell region in the memory cell array 107 is newly assigned to this inputted data. Moreover, the ECC code, such as the LDPC code may newly be added to this inputted data.

The write-in data is loaded to the sense amplifier circuit 109 through the input-and-output terminals 102 and the data buffer 106, and is written in the 16 levels cell region inside the memory cell array 107 according to the address decoded by the column decoder 108 and the row decoder 111 (S604).

The data copy from the 2 levels cell region to the 16 levels cell region is executed in order as mentioned above. When the block BLK of the 2 levels cell region in which all internal data has already been copied to the 16 levels cell region (hereafter, called the copied block BLK) is created with the data copy to the 16 levels cell region from the 2 levels cell region progressing, the copied block BLK may be the object of the erase operation because the data stored in the copied block BLK is unnecessary. Therefore, the flash controller 200 detects whether or not the copied block BLK is created during the data copy operation to the 16 levels cell region from the 2 levels cell region (S605).

When the copied block BLK is created during the data copy operation to the 16 levels cell region from the 2 levels cell region, the flash controller 200 interrupts the data copy operation, and inputs the erase command which directs erase of this copied block BLK to the NAND type flash memory 100. The erase command is transmitted to the command decoder 104 through the input-and-output terminals 102, and the erase operation of the copied block BLK is executed under control of the control signal generating circuit 113 (S606).

In this stage, the number of rewrites for the erased copied block BLK in the 2 levels cell region is incremented by the counter 206. The flash controller 200 updates the number of rewrites management table for the 2 levels cell region on the RAM 203 and also simultaneously updates the number of rewrites management table stored in the memory cell array 107 with non-volatile state (S607).

When the copied block BLK was not created during the data copy operation to the 16 levels cell region from the 2 levels cell region (in the case of No at the step 605), or when the number of rewrites management table for the 2 levels cell region was updated after the copied block had created during the data copy operation to the 16 levels cell region from the 2 levels cell region (in the case of Yes at step 605) and this copied block BLK had been erased, the flash controller 200 detects whether or not the data copy operation for all the data that should be copied to the 16 levels cell region from the 2 levels cell region has completed (S608).

When the copy operation for all the data that should be copied to the 16 levels cell region from the 2 levels cell region has completed, the data write sequence is ended. On the other hand, when the data not yet copied to the 16 levels cell region remains in the 2 levels cell region, the data copy operation to the 16 levels cell region from the 2 levels cell region is continued.

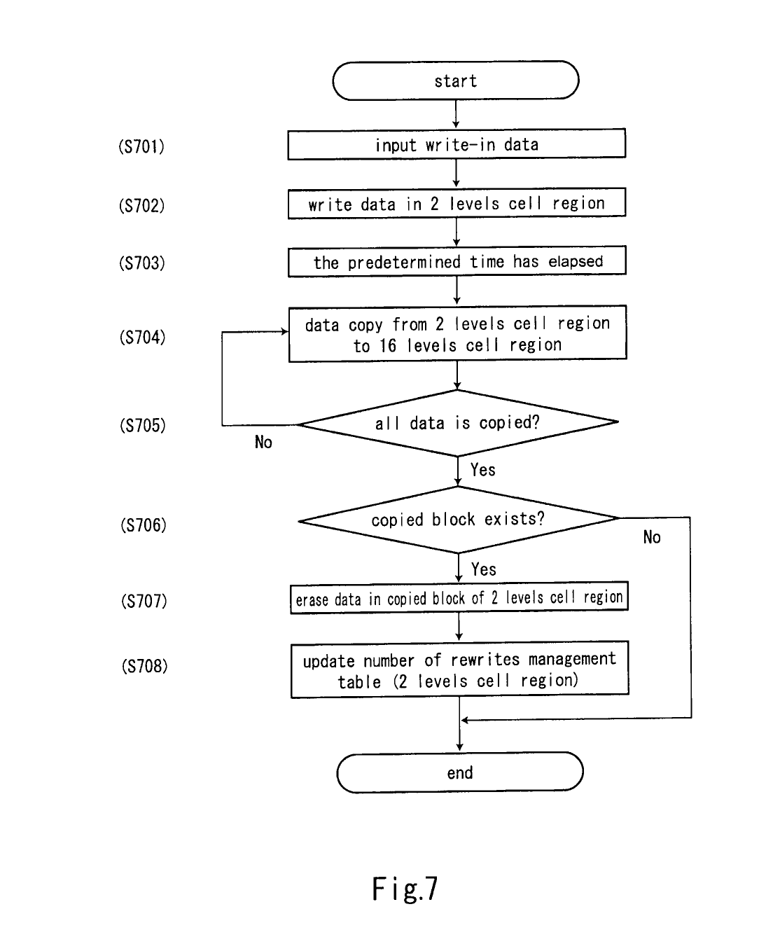

FIG. 7 is a flowchart of the transformational example in which a part of the data write sequence shown in FIG. 6 is changed. The above mentioned data write sequence erases the copied block BLK each time, when the copied block BLK created during the data copy operation.

On the other hand, the data write sequence shown in FIG. 7 erases the copied blocks BLK collectively which exist in the 2 levels cell region, when all the data that should be copied to the 16 levels cell region from the 2 levels cell region has been copied to the 16 levels cell region. Hereafter, the data write sequence shown in FIG. 7 is explained concretely.

In a similar way as shown in FIG. 7, the write-in data inputted into the memory system from the external host system is temporarily stored in the buffer 204 of the flash controller 200. The ECC code is generated by the ECC circuit 205, and the data and ECC parity bits are transmitted to the data buffer 106 through the input-and-output terminals 102 (S701).

The write-in data which has transmitted to the data buffer 106 is loaded to the sense amplifier circuit 109, and is written in the 2 levels cell region inside the memory cell array 107 according to the address decoded by the column decoder 108 and the row decoder 111 (S702).

If the timer 207 inside the flash controller 200 detects that predetermined time has elapsed after access to the memory system from the external host system is completed, the timer 207 notify the information which represents that the predetermined time has elapsed to the CPU 201 (S703).

When the CPU 201 receives the notification from the timer 207, the data copy operation to the 16 levels cell region from the 2 levels cell region, is started. The write-in data stored in the 2 levels cell region is copied to the 16 levels cell region inside the memory cell array 107 in order (S704).

In this stage, different from the data write sequence shown in FIG. 6, even if the copied block BLK is created during the data copy operation with the data copy from the 2 levels cell region to the 16 levels cell region progressing, the data copy operation to the 16 levels cell region from the 2 levels cell region continues. When the copy of all the data that should be copied to the 16 levels cell region from the 2 levels cell region by continuing the data copy operation is completed, the data copy operation is ended (S705).

When the data copy operation to the 16 levels cell region from the 2 levels cell region has been completed, the flash controller 200 detects whether or not the copied block BLK exists in the 2 levels cell region (S706).

If the copied block BLK exists in the 2 levels cell region when the data copy operation to the 16 levels cell region from the 2 levels cell region has been completed, the flash controller 200 inputs the erase command which directs erase operation for this copied block BLK to the NAND type flash memory 100. The erase command is transmitted to the command decoder 104 through the input-and-output terminals 102, and the erase operation of the copied block BLK is executed under control of the control signal generating circuit 113 (S707).

In this stage, the number of rewrites for the erased copied block BLK in the 2 levels cell region is incremented by the counter 206. The flash controller 200 updates the number of rewrites management table for the 2 levels cell region on the RAM 203 and also simultaneously updates the number of rewrites management table stored in the memory cell array 107 with non-volatile state (S708).

When the copied block BLK does not exist in the 2 levels cell region when the data copy operation to the 16 levels cell region from the 2 levels cell region has been completed (in the case of No at the step S706), or when the number of rewrites management table for the 2 levels cell region was updated after erasing the copied block BLK when the copied block BLK exists in the 2 levels cell region when the data copy operation to the 16 levels cell region from the 2 levels cell region has been completed (in the case of Yes at the step S706), the data write sequence is ended.

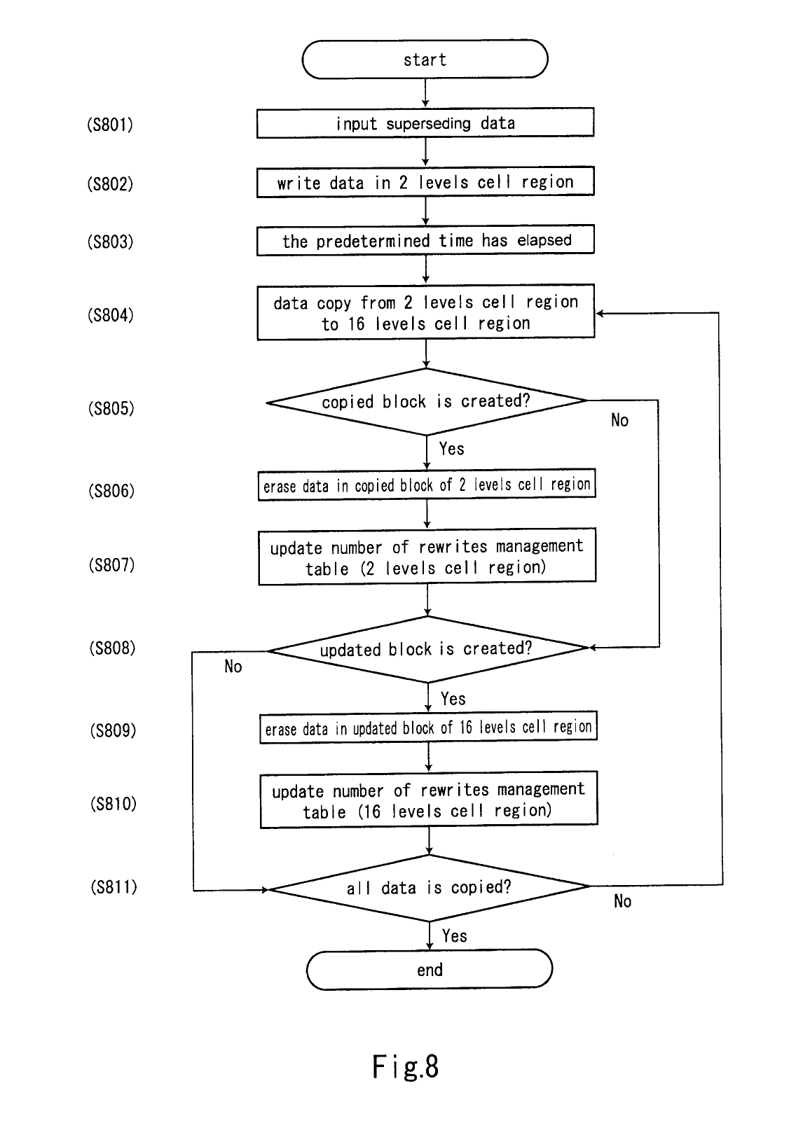

The data update sequence for the data stored in the 16 levels cell region is explained with reference to FIG. 8. In order to simplify the explanation, the case where the data stored in the arbitrary block BLK of the 16 levels cell region is all updated is assumed.

The update data inputted into the memory system from the external host system is temporarily stored in the buffer 204 of the flash controller 200. The ECC code is generated by the ECC circuit 205, and the update data and ECC parity bits are transmitted to the data buffer 106 through the input-and-output terminals 102 (S801).

The superseding data which has transmitted to the data buffer 106 is loaded to the sense amplifier circuit 109, and is written in the 2 levels cell region inside the memory cell array 107 according to the address decoded by the column decoder 108 and the row decoder 111 (S802).

If the timer 207 inside the flash controller 200 detects that predetermined time has elapsed after access to the memory system from the external host system is completed, the timer 207 notify the information which represents that the predetermined time has elapsed to the CPU 201 (S803).

When the CPU 201 receives the notification from the timer 207, the data copy operation to the 16 levels cell region from the 2 levels cell region is started. The update data copied to the 16 levels cell region from the 2 levels cell region is written in order in empty blocks (erased blocks) BLK different from the blocks BLK in which the old data which should be updated is stored (S804).

The flash controller 200 detects whether or not the copied block BLK is created during the data copy operation to the 16 levels cell region from the 2 levels cell region (S805).

When the copied block BLK is created during the data copy operation to the 16 levels cell region from the 2 levels cell region, the flash controller 200 interrupts the data copy operation, and inputs the erase command which directs erase of this copied block BLK to the NAND type flash memory 100. The NAND type flash memory 100 erases the copied block BLK based on the inputted erase command (S806).

In this stage, the number of rewrites for the erased copied block BLK in the 2 levels cell region is incremented by the counter 206. The flash controller 200 updates the number of rewrites management table for the 2 levels cell region on the RAM 203 and also simultaneously updates the number of rewrites management table stored in the memory cell array 107 with non-volatile state (S807).

In the blocks BLK storing the old data which should be updated of the 16 levels cell region, when arbitrary one block BLK in which all internal old data has been replaced with the update data (hereafter, called the updated block BLK) is created, with the data copy operation to the 16 levels cell region from the 2 levels cell region progressing, the updated block BLK may be the object of the erase operation because the data stored in the updated block BLK is unnecessary. Therefore, the flash controller 200 detects whether or not the updated block BLK is created during the data copy operation to the 16 levels cell region from the 2 levels cell region (S808).

When the updated block BLK is created during the data copy operation to the 16 levels cell region from the 2 levels cell region, the flash controller 200 interrupts the data copy operation, and inputs the erase command which directs erase of this updated block BLK to the NAND type flash memory 100. The erase command is transmitted to the command decoder 104 through the input-and-output terminals 102, and the erase operation for the updated block BLK is executed under control of the control signal generating circuit 113 (S809).

In this stage, the number of rewrites for the erased updated block BLK in the 16 levels cell region is incremented by the counter 206. The flash controller 200 updates the number of rewrites management table for the 16 levels cell region on the RAM 203 and also simultaneously updates the number of rewrites management table stored in the memory cell array 107 with non-volatile state (S810).

When neither the copied block BLK nor the updated block BLK is created in the data copy operation to the 16 levels cell region from the 2 levels cell region (in the case of No at the step S805 and No at the step S808), or when the number of rewrites management table for the 2 levels cell region is updated after erasing the created copied block BLK, and the updated block BLK is not created (in the case of Yes at the step S805 and No at the step S808), or when the copied block BLK is not created and the number of rewrites management table for the 16 levels cell region is updated after erasing the created updated block BLK (in the case of No at the step S805 and Yes at the step S808), or when the number of rewrites management table for the 2 levels cell region is updated after erasing the created copied block BLK and the number of rewrites management table for the 16 levels cell region is updated after erasing the created updated block BLK (in the case of Yes at the step S805 and Yes at the step S808), the flash controller 200 detects whether or not the copy of all the update data that should be copied to the 16 levels cell region from the 2 levels cell region is completed (S811).

When the data copy operation of all the update data that should be copied to the 16 levels cell region from the 2 levels cell region is completed, the data update sequence is ended. On the other hand, when the update data which is not yet copied remains in the 2 levels cell region, the data copy operation to the 16 levels cell region from the 2 levels cell region is continued.

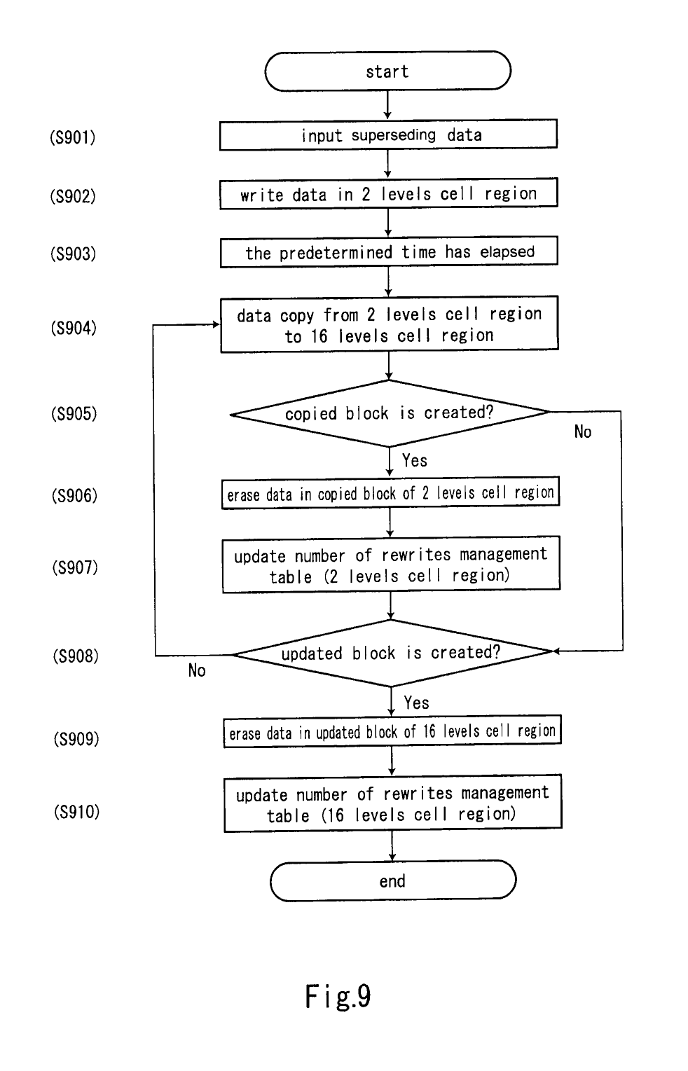

FIG. 9 illustrates a flowchart in a data update sequence of a semiconductor storage system in accordance with a transformational example of a first embodiment of the present invention. In FIG. 9, the data update sequence shown in FIG. 8 is partly changed. The data update sequence shown in FIG. 8 erases the updated block BLK each time, when the updated block BLK is created during the data copy operation.

On the other hand, the data update sequence shown in FIG. 9 erases the updated blocks BLK collectively which exist in the 16 levels cell region, when all the data that should be copied to the 16 levels cell region from the 2 levels cell region has been copied to the 16 levels cell region. Hereafter, the data update sequence shown in FIG. 9 is explained concretely.

In a similar way as shown in FIG. 8, the superseding data inputted into the memory system from the external host system is temporarily stored in the buffer 204 of the flash controller 200. The ECC code is generated by the ECC circuit 205, and the data and ECC parity bits are transmitted to the data buffer 106 through the input-and-output terminals 102 (S901).

The update data which has transmitted to the data buffer 106 is loaded to the sense amplifier circuit 109, and is written in the 2 levels cell region inside the memory cell array 107 according to the address decoded by the column decoder 108 and the row decoder 111 (S902).

If the timer 207 inside the flash controller 200 detects that predetermined time has elapsed after access to the memory system from the external host system is completed, the timer 207 notify the information which represents that the predetermined time has elapsed to the CPU 201 (S903).

When the CPU 201 receives the notification from the timer 207, the data copy operation to the 16 levels cell region from the 2 levels cell region is started. The update data stored in the 2 levels cell region is copied to empty blocks (erased blocks) BLK different from the blocks BLK in order in which the old data which should be updated is stored in the 16 levels cell region inside the memory cell array 107 (S904).

The flash controller 200 detects whether or not the copied block BLK is created during the data copy operation to the 16 levels cell region from the 2 levels cell region (S905). When the copied block BLK is created during the data copy operation to the 16 levels cell region from the 2 levels cell region, the copied block BLK of the 2 levels cell region is erased (S906).

The number of rewrites for the copied block BLK in which data is erased in the 2 levels cell region is incremented by the counter 206. The flash controller 200 updates the number of rewrites management table for the 2 levels cell region on the RAM 203 and also simultaneously updates the number of rewrites management table stored in the memory cell array 107 with non-volatile state (S907).

In this stage, different from the data update sequence shown in FIG. 8, even if the updated block BLK is created during the data copy operation with the data copy from the 2 levels cell region to the 16 levels cell region progressing, the updated block BLK is not erased and the data copy operation to the 16 levels cell region from the 2 levels cell region continues.

When the copied block BLK is not created in the 2 levels cell region during the data copy operation to the 16 levels cell region from the 2 levels cell region (in the case of No at the step 905), or when the number of rewrites management table for the 2 levels cell region was updated after erasing the copied block BLK which is created during the data copy operation to the 16 levels cell region from the 2 levels cell region (in the case of Yes at the step S905), the flash controller 200 detects whether or not the copy of all the update data that should be copied to the 16 levels cell region was completed.

When the copy of all the update data that should be copied to the 16 levels cell region from the 2 levels cell region is completed, the data copy operation is ended. And thereafter, the flash controller 200 inputs the erase command into the NAND type flash memory 100, and the data in the updated blocks BLK is erased which exists at the time when the data copy operation to the 16 levels cell region from the 2 levels cell region is completed (S909).

The number of rewrites for the updated block BLK in which the old data is erased in the 16 levels cell region is incremented by the counter 206. The flash controller 200 updates the number of rewrites management table for the 16 levels cell region on the RAM 203 and also simultaneously updates the number of rewrites management table stored in the memory cell array 107 with non-volatile state (S910).

In addition, also in the data update sequence, like the case where the data write-in sequence mentioned above, the copied block BLK of the 2 levels cell region collectively may be erased when the data copy operation is completed.

Moreover, the data copy operation to the 16 levels cell region from the 2 levels cell region mentioned above is performed in the state of a background at time when no access is required by the external host system.

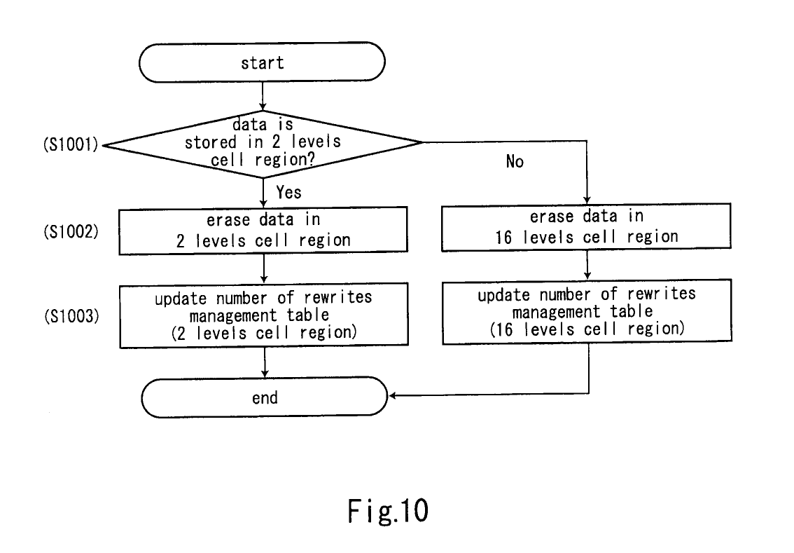

FIG. 10 illustrates a flowchart in an erase sequence of a semiconductor storage system in accordance with a first embodiment of the present invention. In FIG. 10, the data erase sequence is explained in case the data stored in the 2 levels cell region or the 16 levels cell region is erased

As mentioned above, the write-in data inputted into the memory system from the external host system may be stored in the 16 levels cell region when the data copy operation has already completed, or on the other hand, may stored in the 2 levels cell region when the data copy operation has not yet completed. Therefore, it is necessary for the flash controller 200 to distinguish that whether or not the data pointed by the address inputted into the memory system is stored in the 2 levels cell region and whether or not the data is stored in the 16 levels cell region (S1001).

If the inputted address points the data stored in the 2 levels cell region inside the NAND type flash memory 100 (in the case of Yes at the step S1001), the flash controller 200 inputs the address corresponding to this data and the erase command into the NAND type flash memory 100. The NAND type flash memory 100 erases the data stored in the 2 levels cell region based on the inputted address. The number of rewrites of the block BLK in which the data is erased in the 2 levels cell region is incremented, and the contents of the number of rewrites management table for the 2 levels cell region are updated (S1002).

On the other hand, the inputted address does not point the data stored in the 2 levels cell region inside the NAND type flash memory 100, i.e., the inputted address points the data stored in the 16 levels cell region (in the case of No at the step S1001), the flash controller 200 inputs the address corresponding to this data and the erase command into the NAND type flash memory 100. The NAND type flash memory 100 erases the data stored in the 16 levels cell region based on the inputted address. The number of rewrites for the block BLK of which the data is erased in the 16 levels cell region is incremented and the contents of the number of rewrites management table in the 16 levels cell region are updated (S1003).

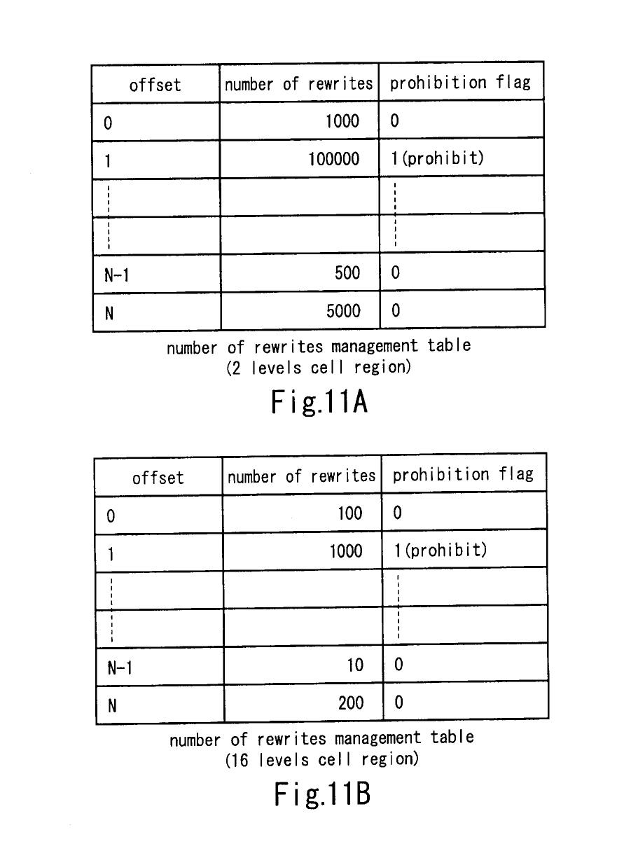

The method of controlling the number of rewrites for each block BLK in the memory cell array 107 using the number of rewrites management table which mentioned above is explained with reference to FIG. 11 to FIG. 14.

In the present embodiment, the 2 levels cell region and the 16 levels cell region are managed so that each block BLK does not exceed the guaranteed number of rewrites by setting a write prohibition flag for the block BLK which is used for the predetermined number of rewrites on the number of rewrites management table.

That is, the flash controller 200 watches the number of rewrites management table. The flash controller 200 controls the blocks BLK of the 2 levels cell region not to exceed the guaranteed number of rewrites by comparing with 100,000 times which is the guaranteed number of rewrites in the 2 levels cell region, and controls the blocks BLK of 16 levels cell region not to exceed the guaranteed number of rewrites by comparing with 1,000 times which is the guaranteed number of rewrites in the 16 levels cell region.

For example, the number of rewrites management table for the 2 levels cell region shown in FIG. 11A illustrates the case where the block BLK of offset=“0” was erased for 1,000 times, the block BLK of offset=“1” was erased for 100,000 times, the block BLK of offset=“N−1” was erased for 500 times, and the block BLK of offset=“N” was erased for 5000 times.

Since the number of rewrites for the block BLK of offset=“1” has already reached 100,000 times which is the guaranteed number rewrites for the 2 levels cell region, corresponding prohibition flag is set to “1” and data rewriting is forbidden henceforth. Since the blocks BLK except the block BLK of offset=“1” is not reached the guaranteed number of rewrites, corresponding prohibition flag remains “0” and data rewriting is permitted.

The number of rewrites management table for the 16 levels cell region shown in FIG. 11B illustrates the case where the block BLK of offset=“0” was erased for 100 times, the block BLK of offset=“1” was erased for 1,000 times, the block BLK of offset=“N−1” was erased for 10 times, and the block BLK of and offset=“N” is erased for 200 times.

Since the number of rewrites for the block BLK of offset=“1” has already reached 1,000 times which is the guaranteed number of rewrites on the 16 levels cell region, corresponding prohibition flag is set to “1” and data rewriting is forbidden henceforth. Since the blocks BLK except the block BLK of offset=“1” is not reached the guaranteed number of rewrites, corresponding prohibition flag remains “0” and data rewriting is permitted.

Furthermore, in the present embodiment, the equation of the number of rewrites (wear leveling) is executed in the 2 levels cell region and the 16 levels cell region respectively by the following methods.

For example, if a comparatively mass file like application software is stored in the NAND type flash memory 100 and is rarely updated, the block BLK which stores this file is rarely rewritten. That is, the block BLK remains in the memory cell array 107 in such state that the number of rewrites is very few.

On the other hand, since other frequently updated regions, such as data regions used by this application software are rewritten repeatedly, the number of rewrites among both becomes the very imbalanced state. If such a state is left, although the block BLK of which the number of rewrites is very few still exists, much the blocks BLK of which prohibition flag is set to “1” by repeating data rewriting to the guaranteed number of rewrites are created. Consequently, the 2 levels cell region and the 16 levels cell region cannot be used efficiently to the guaranteed number of rewrites.

Therefore, in the present embodiment, the wear leveling is executed by replacing the data stored in the block BLK which is not rewritten (the number of rewrites is few), with the data stored in the block BLK which is rewritten frequently (the number of rewrites is much). Hereafter, the wear leveling sequence is explained concretely.

First, the case where the wear leveling is executed in the 16 levels cell region is explained. The condition to activate the wear leveling in the 16 levels cell region may be set up so that it may be activated, for example, “when the number of rewrites for any of blocks BLK in the 16 levels cell region reaches the predetermined ratio (the second predetermined ratio) of the guaranteed number of rewrites on the 16 levels cell region”. In the present embodiment, the wear leveling is activated, for example, in the condition that the number of rewrites reached 95% of the guaranteed number of rewrites, i.e., the condition that the number of rewrites reached 950 times.

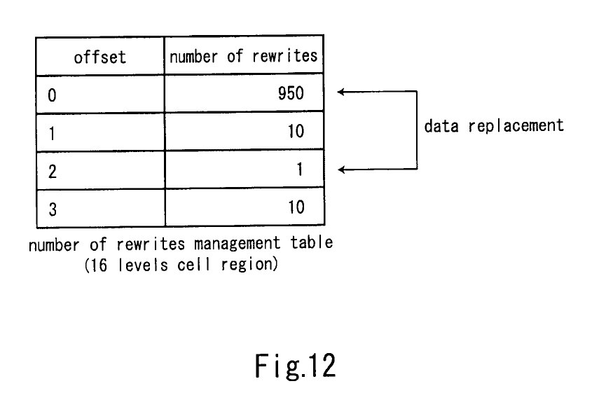

FIG. 12 shows the example of the number of rewrites management table for the 16 levels cell region in the condition that wear leveling is activated. As shown in FIG. 12, the number of rewrites for the block BLK of offset=“0” to offset=“3” is 950 times, 10 times, 1 time, and 10 times, respectively, and the extreme difference on the number of rewrites for each block BLK occurs.

The data stored in the block BLK of offset=“2” is not updated after writing in once. On the other hand, the block BLK of offset=“0” is rewritten frequently, and the number of rewrites for the block BLK of offset=“0” has reached 950 times which is the condition to activate the wear leveling.

When the wear leveling starts, data exchange operation which replaces the data stored in the block BLK of offset=“0” which reached the predetermined ratio of the guaranteed number of rewrites with the data stored in the block BLK of offset=“2” of which the number of rewrites is the least.

This data exchange operation may be executed by judgment on a memory system's own in the background state where an external host system does not request an access to the memory system, or may be executed according to the predetermined command inputted from the external host system.

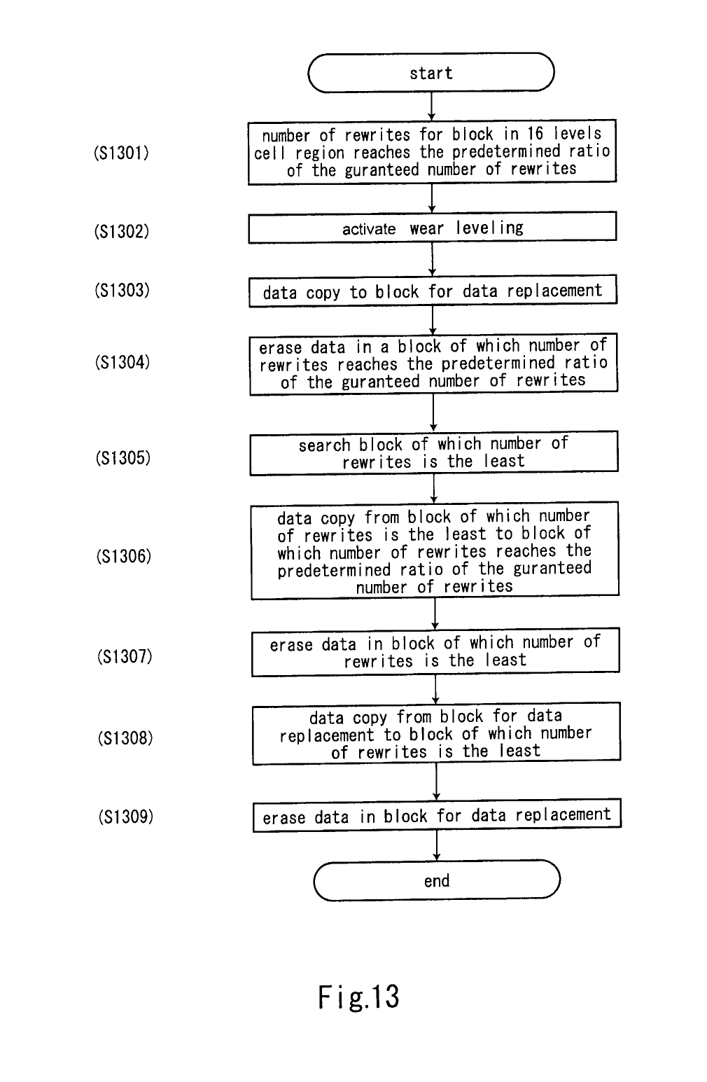

The data exchange operation when the wear leveling starts is explained with reference to FIG. 13. FIG. 13 illustrates a flowchart which shows the wear leveling sequence in the 16 levels cell region.

As mentioned above, when the flash controller 200 detects that the number of rewrites for any of blocks BLK in the 16 levels cell region reached the predetermined ratio of 1,000 times which is the guaranteed number of rewrites on the 16 levels cell region (S1301), the wear leveling starts (S1302).

The arbitrary empty block BLK (hereafter, called the block BLK for data replacement) in the 16 levels cell region is prepared for data exchange, and the data stored in the block BLK (in the case of FIG. 13, the block BLK of offset=“0”) of which the number of rewrites reached the predetermined ratio of the guaranteed number of rewrites on the 16 levels cell region is copied to the block BLK for data replacement (S1303).

If the data copy to the block BLK for data replacement from the block BLK of which number of rewrites reached the predetermined ratio of the guaranteed number of rewrites on the 16 levels cell region is completed, the data stored in the block BLK of which number of rewrites reached the predetermined ratio of the guaranteed number of rewrites is erased. In this stage, the number of rewrites for the erased block BLK is incremented by the counter 206, and the number of rewrites management table for the 16 levels cell region is updated (S1304).

The flash controller 200 searches the block BLK of which the number of rewrites is the least in the 16 levels cell region (S1305). The data stored in the searched the block BLK (in the case of FIG. 12, the block BLK of offset=“2”) of which number of rewrites is the least is copied to the erased block BLK which reached the predetermined ratio of the guaranteed number of rewrites (S1306).

If the data copy to the block BLK which reached the predetermined ratio of the guaranteed number of rewrites from the block BLK of which the number of rewrites is the least is completed, the data stored in the block BLK of which the number of rewrites is the least is erased. In this stage, the number of rewrites for the erased block BLK of which the number of rewrites is the least is incremented by the counter 206, and the number of rewrites management table for the 16 levels cell region is updated (S1307).

The data evacuated to the block BLK for data replacement is returned to the block BLK of which number of rewrites is the least (S1308).

After completing the data copy to the block BLK of which number of rewrites is the least from the block BLK for data replacement, since the data stored in this block BLK for data replacement is unnecessary, the data stored in the block BLK for data replacement is erased. The data exchange operation ends. In this stage, the erased block BLK for data replacement is incremented by the counter 206 and the number of rewrites management table for the 16 levels cell region is updated (S1309).

By applying the above wear leveling sequence to the memory system, it is possible to move the data stored in the block BLK which is not rewritten to the block BLK which is rewritten frequently and is approaching the lifetime (the guaranteed number of rewrites).

Thereby, the block BLK which reached the predetermined ratio of the guaranteed number of rewrites is expected not to be exposed to a rewriting cycle henceforth and to continue holding the number of rewrites at the time when the wear leveling was activated. On the other hand, the block BLK of which number of rewrites was extremely few is expected to be used for data rewriting.

In addition, the blocks BLK in the 16 levels cell region is not necessarily set as the object of the wear leveling. That is, when the block BLK which stores important data in the 16 levels cell region exists, in order to avoid the risk of the data lost by the power supply interception in the wear leveling, this block BLK may be excluded from the object of the wear leveling.

Although the wear leveling sequence mentioned above is explained with the 16 levels cell region as an example, the similar control method is applied to the 2 levels cell region. Specifically, the condition to activate the wear leveling in the 2 levels cell region may be set up so that it may be activated, for example, “When the number of rewrites for any of blocks BLK in the 2 levels cell region reaches the predetermined ratio (the first predetermined ratio) of the guaranteed number of rewrites on the 2 levels cell region”. In the present embodiment, the wear leveling is activated, for example, in the condition that the number of rewrites reached 95% of the guaranteed number of rewrites, i.e., the condition that the number of rewrites reached 95,000 times.

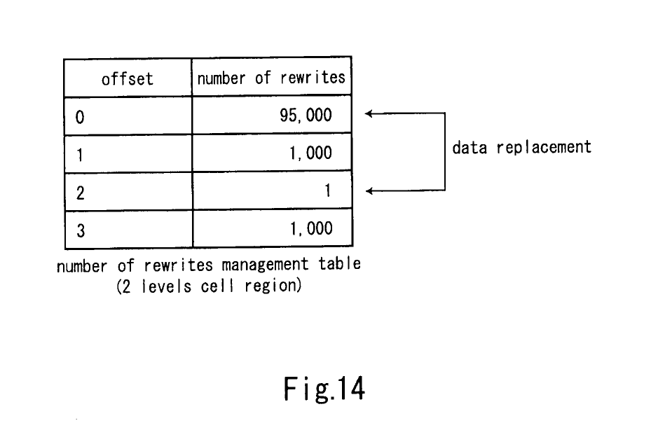

FIG. 14 illustrates an example of the number of rewrites management table for the 2 levels cell region in the condition that the wear leveling is activated. As shown in FIG. 14, the number of rewrites for the block BLK of offset=“0” to offset=“3” is 95,000 times, 1,000 times, 1 time, and 1,000 times, respectively, and the extreme difference on the number of rewrites for each block BLK occurs.

The data stored in the block BLK of offset=“2” is not updated after writing in once. On the other hand, the block BLK of offset=“0” is rewritten frequently, and the number of rewrites for the block BLK of offset=“0” has reached 95,000 times which is the condition to activate the wear leveling.

When the wear leveling starts, data exchange operation which replaces the data stored in the block BLK of offset=“0” which reached the predetermined ratio of the guaranteed number of rewrites with the data stored in the block BLK of offset=“2” of which the number of rewrites is the least.

Subsequent data exchange operation is the same as the case of the 16 levels cell region mentioned above, namely, the data exchange operation is executed by using the empty block BLK (the block BLK for data replacement) in the 2 levels cell region.

Moreover, in the present embodiment, the block BLK in the 2 levels cell region which stores important management data, such as the farm wear, or other data for control of the flash controller 200, is excluded from the object of the wear leveling in order to avoid the risk of the data lost by the power supply interception in the wear leveling etc.

Moreover, the block BLK which constitutes the buffer region in the 2 levels cell region with which the data is copied to the 16 levels cell region is treated to be the object of the wear leveling.

Moreover, the buffer region in the 2 levels cell region is preferable to be used cyclically in order to avoid that data writing concentrates on the specific block BLK in the buffer region.

As mentioned above, the 16 levels cell region and the 2 levels cell region become possible to be managed efficiently by controlling the number of rewrites for each region based on the guaranteed number of rewrites on the 16 levels cell region (1,000 times) and the guaranteed number of rewrites on the 2 levels cell region (100,000 times).

Especially, when executing the data writing to the 16 levels cell region through the 2 levels cell region like the present embodiment, since it is assumed that the 2 levels cell region is exposed to a frequent rewriting cycle, controlling the number of rewrites based on the guaranteed number of rewrites on each region is very effective.

Moreover, in the present embodiment, although the case where the wear leveling is activated when the number of rewrites for the 2 levels cell region and the 16 levels cell region reached 95% of the guaranteed number of rewrites on each region was explained, the wear leveling may be activated when the number of rewrites for the 2 levels cell region and the 16 levels cell region reaches a mutually different ratio of the guaranteed number of rewrites on each region.

Moreover, if the predetermined ratio of the guaranteed number of rewrites is too small, the wear leveling is activated frequently and which prevent the memory system from operating at high speed. Therefore it is preferable for the predetermined ratio to be set, for example, 90% or more of the guaranteed number of rewrites.

Moreover, when the block BLK which constitutes the 16 levels cell region reaches the guaranteed number of rewrites, the flash controller 200 may newly use this block BLK as the block BLK which constitutes the 2 levels cell region.

However, when newly using the block BLK which has been used in the 2 levels cell region as the 16 levels cell region, it is not preferable to use the block BLK which has already used 1,000 times in the 2 levels cell region as the 16 levels cell region henceforth, because such a block BLK has already reached the guaranteed number of rewrites on the 16 levels cell region.

Moreover, in the present embodiment, the block BLK which constitutes the 2 levels cell region is divided into the region included in the object of the wear leveling and the region excluded from the object of the wear leveling. The region included in the object of the wear leveling includes the block BLK which constitutes the buffer region with which the write-in data is copied to the 16 levels cell region is executed. The region excluded from the object of the wear leveling includes the block BLK which stores important management data, such as the farm wear or other data for control of the flash controller 200. However, the 2 levels cell region does not necessarily include the region excluded from the wear leveling.

For example, the important management data, such as the farm wear and other data for control of the flash controller 200 may be stored in another storage area which consists of FeRAM (Ferro electric Random Access Memory) etc.

Moreover, whether or not a certain block BLK is set as the object of the wear leveling is suitably determined in consideration of the importance of the data stored in the block BLK, or update frequency, etc.

Moreover, in the present embodiment, the case where once write-in data is transmitted into the buffer region of the 2 levels cell region at high speed, and thereafter, the data is transmitted to the 16 levels cell region from the 2 levels cell region (the buffer region) in the state of a background at time when no access is required by the external host system was explained.

However, when write-in data is inputted continuously from an external host system, and the number of the empty block BLK in the buffer region becomes extremely few, the flash controller 200 may execute data copy from the 2 levels cell region to the 16 levels cell region compulsorily.

Moreover, in the present embodiment, although the NAND type flash memory 100 which includes the 2 levels cell region as the first memory region and the 16 levels cell region as the second memory region was explained, the NAND type flash memory 100 may include the 2 levels cell region as the first memory region and the 8 levels cell region as the second memory region, or may include some memory region with other combination.

Moreover, in the present embodiment, although the contents of the number of rewrites management table is defined as the number of erases for the block BLK, the contents may be the information related with the number of erases. For example, the contents may be the value which is incremented when erase operation was executed 10 times.

Moreover, logical address inputted from an external host system is translated to physical address on a logical-to-physical translation table by the flash controller 200. First, the logical address inputted from the external host system is translated to the physical address corresponding to the 2 levels cell region. And then, when the data stored in the 2 levels cell region is copied to the 16 levels cell region, the logical-to-physical translation table is updated so that the logical address is assigned to the physical address corresponding to the 16 levels cell region.

Moreover, old data stored in the copied blocks BLK or the updated blocks BLK are may be erased anytime. For example, an invalid flag may be applied to the copied blocks BLK or the updated blocks BLK in the logical-to-physical translation table or the number of rewrites management table, and erase operation may be executed before programming.

Moreover, various methods can be considered about the creation method of the number of rewrites management table on the RAM 203. When the number of blocks BLK in the memory cell array 107 is not much, it is possible to prepare the number of rewrites management table for all blocks BLK on the RAM 203.

On the other hand, when the number of rewrites management table for all blocks BLK cannot be prepared on the RAM 203, since the storage capacity of the NAND type flash memory 100 is large and the number of blocks BLK contained in the memory cell array 107 is enormous, it is also possible to prepare only the number of rewrites management table for partial blocks BLK (zone) on the RAM 203, and to save the capacity of the RAM 203. The zone is constituted from a plurality of blocks BLK obtained by dividing the memory cell array 107 into the predetermined number of segments.

In this case, when the data stored in the block BLK included in a segment which is not prepared on the RAM 203 is erased, the information on this segment is newly read from the memory cell array 107 on the RAM 203, and the number of rewrites management table is updated (hereafter, called zone management).

Moreover, various cases can be considered about the timing of updating the number of rewrites management table. The contents of the number of rewrites management table on the RAM 203 are updated, when any of the blocks BLK in the memory cell array 107 is erased.

However, the information for the number of rewrites management table stored in the memory cell array 107 with non-volatile state is not necessarily updated whenever the number of rewrites management table on the RAM 203 is updated.

The information for the number of rewrites management table stored in the memory cell array 107 with non-volatile state may be updated when the flash controller 200 receives the information which notify turning off the power supply from an external host system, or may be collectively updated when the erase operation is executed for predetermined number of times (for example, 100 times).

Moreover, in the zone management mentioned above, the information for the number of rewrites management table stored in the memory cell array 107 with non-volatile state may be updated, when the switch of zones occurs. By these methods, it is possible to reduce the influence on the increase in the number of rewrites originated in updating of the number of rewrites management table.

Moreover, in the present embodiment, the memory cell array 107 inside one chip of the NAND type flash memory 100 is divided into the 2 levels cell region and the 16 levels cell region. However, if a memory system includes two or more chips of the NAND type flash memory, a certain chip as a whole may be used as the 2 levels cell region, and other chip as a whole may be used as the 16 levels cell region.

In this case, the chip in which the predetermined ratio of the blocks BLK used as the 16 levels cell region reached the guaranteed number of rewrites may be henceforth used as the 2 levels cell region.

Moreover, in the present embodiment, although in the case where the unit which manages the number of rewrites is a block BLK unit was explained, the number of rewrites may be managed in two or more blocks BLK as one unit.

Moreover, in the memory system concerning the present embodiment, the page buffer PB inside the sense amplifier circuit 109 is connected with either the even bit line BLe or the odd bit line BLo alternatively through the selection circuit 110. However, one page buffer PB may be connected with one bit line BL without the selection circuit 110.

Moreover, in the present embodiment, the NAND cell unit NU includes memory cells MC0 to MC31 and the control gate of the memory cell MC of the same line respectively extends in the direction of a row and commonly connected each other. The commonly connected control gates constitute the word lines WL0 to WL31.

However, the NAND cell unit NU may include memory cells MC0 to MC63. The control gate of the memory cell MC of the same line respectively extends in the direction of a row and commonly connected each other. The commonly connected control gates constitute the word lines WL0 to WL63.

Moreover, in the memory system concerning the present embodiment, although the structure using the floating gate as the memory cell MC was explained, the structure using the ONO (silicon oxide-silicon nitride-silicon oxide) layers may be available. The threshold voltage as the transistor is controlled by the amount of electrons trapped in the silicon nitride layer.

Moreover, in the present embodiment, although the case where a memory system includes a NAND type flash memory was explained, a memory system may include various type of flash memories, such as NOR type, AND type, DINOR type, or combination of them.

Moreover, the present embodiment may be applied to other type of memories, such as OUM (Ovonics Unified Memory) which uses a chalcogen compound, MRAM (Magnetic Random Access Memory) which is generally known as to be little limit in the number of rewrites, FeRAM which uses a ferroelectric substance, PCRAM (Phase Change Random Access Memory), ReRAM (Resistive Random Access Memory) etc.

Moreover, the memory system concerning the present embodiment may be used in a memory card, like the following second embodiment, or may be used in packages, such as MCP (Multi Chip Package) which includes a plurality of chips stacked one another, or BGA (Ball Grid Array) package etc.

### Modified Example of First Embodiment

The modified example of the wear leveling sequence in the first embodiment is shown below. Here, the case where the wear leveling is executed in the 16 levels cell region is explained.

In the present modified example, the wear leveling is activated “when the difference of the number of rewrites between a block BLK of which number of rewrites is the most and a block BLK of which number of rewrites is the least reaches the predetermined number of times (the second limit) in the 16 levels cell region”.

This wear leveling sequence controls the difference of the number of rewrites for each block BLK in the 16 levels cell region to be within fixed limits by exchanging data stored in a block BLK of which number of rewrites is the most for data stored in a block BLK of which number of rewrites is the least.

For example, if the predetermined number of times is 100 times, the wear leveling is activated when the difference of the number of rewrites between a block BLK of which number of rewrites is the most and a block BLK of which number of rewrites is the least reaches 100 times.

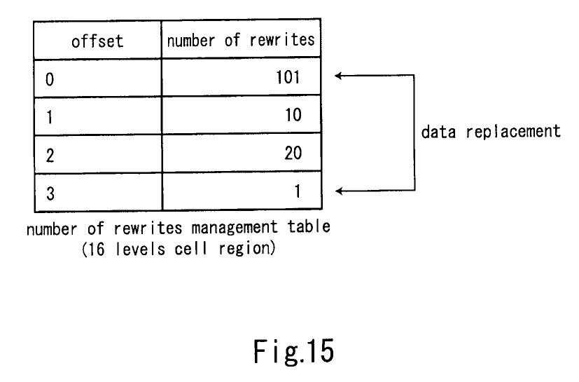

FIG. 15 illustrates an example of the number of rewrites management table for the 16 levels cell region when the wear leveling starts. As shown in FIG. 15, the number of rewrites for the block BLK of offset=“0” to offset=“3” is 101 times, 10 times, 20 times, and 1 time, respectively, and the difference of the number of rewrites between a block BLK of offset=“0” of which number of rewrites is the most and a block BLK of offset=“3” of which number of rewrites is the least reaches 100 times which is the condition to activate the wear leveling.

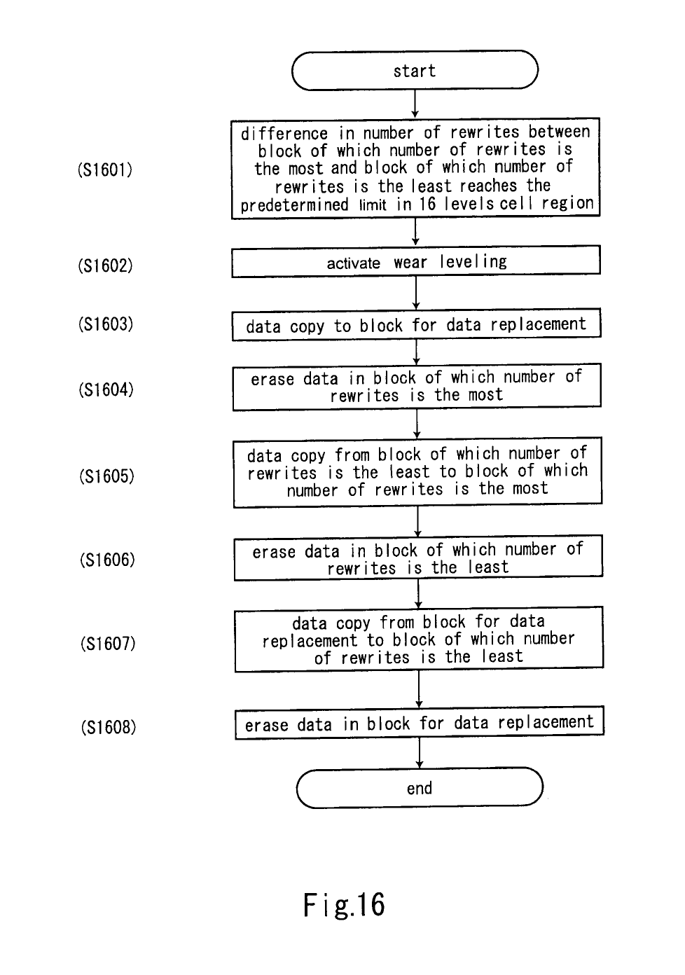

The data exchange operation during the wear leveling is explained with reference to FIG. 16. FIG. 16 illustrates a flowchart in the wear leveling sequence when wear leveling starts in the 16 levels cell region.

The flash controller 200 is watching over the number of rewrites management table for the 16 levels cell region and compares the number of rewrites with the predetermined number of times (for example, 100 times). The flash controller 200 activate the wear leveling when the difference of the number of rewrites between a block BLK of which number of rewrites is the most and a block BLK of which number of rewrites is the least in the 16 levels cell region reaches the predetermined number of times (S1601, S1602).

The flash controller 200 assigns an empty block BLK to the block BLK for data replacement in the 16 levels cell region, and the data stored in the block BLK (in the case of FIG. 16, the block BLK of offset=“0”) of which number of rewrites is the most is copied to the block BLK for data replacement (S1603).

When the data copy to the block BLK for data replacement from the block BLK of which number of rewrites is the most has completed, the data stored in the block BLK of which number of rewrites is the most is erased (S1604).

The flash controller 200 copies data stored in the block BLK (in the case of FIG. 16, the block BLK of offset=“3”) of which the number of rewrites is the least to the block BLK of which the number of rewrites is the most and data stored was previously erased in the 16 levels cell region (S1605).

When the data copy to the block BLK of which number of rewrites is the most from the block BLK of which number of rewrites is the least is completed, data stored in the block BLK of which number of rewrites is the least is erased (S1606).

The data evacuated to the block BLK for data replacement is returned to the block BLK of which number of rewrites is the least (S1607).

After completing the data copy to the block BLK of which number of rewrites is the least from the block BLK for data replacement, data stored in the block BLK for data replacement is erased. The data exchange operation ends (S1608).

By applying the above wear leveling sequence to the memory system, it is possible to continue using the memory cell array 107 without generating an extreme difference on the number of rewrites for all blocks BLK in the 16 levels cell region.

In addition, the similar control method is applied to the 2 levels cell region based on the guaranteed number of rewrites on the 2 levels cell region. Specifically, the condition to activate the wear leveling in the 2 levels cell region is set up so that it may be activated, for example, “when the difference of the number of rewrites between a block BLK of which number of rewrites is the most and a block BLK of which number of rewrites is the least reaches the predetermined number of times (the first limit) in the 2 levels cell region”.

If the wear leveling starts, the data stored in the block BLK of which the number of rewrites is the most is exchanged with data stored in the block BLK of which number of rewrites is the least. Moreover, mutually different wear leveling sequence may be applied to the 2 levels cell region and the 16 levels cell region.

Moreover, in the present embodiment, the block BLK in the 2 levels cell region which stores important management data, such as the farm wear, or other data for control of the flash controller 200, is excluded from the object of the wear leveling in order to avoid the risk of the data lost by the power supply interception in the wear leveling etc. Such blocks BLK to which the wear leveling is not applied may be excluded from the object of comparing the number of rewrites.

As explained above embodiment, the semiconductor storage system which is capable of using efficiently a plurality of memory regions in which storable bits are mutually different is supplied for users.

### Second Embodiment

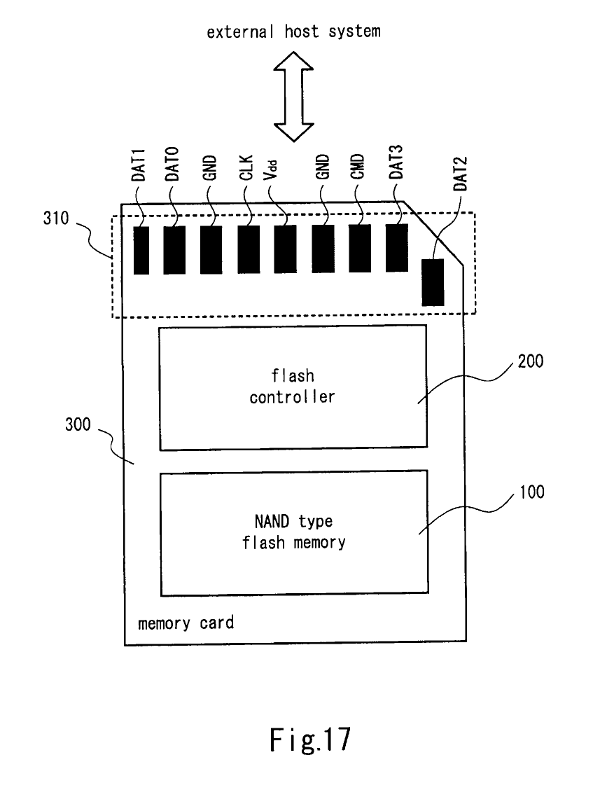

FIG. 17 illustrates a block diagram of the memory card 300 in accordance with a second embodiment. The memory card 300 contains the memory system concerning the first embodiment mentioned above.

The memory card 300 is formed like the SD memory card having nine terminals and is used as an external memory device for a external host system (not shown). Specifically, the external host system can be one of various kinds of electronic devices, such as a personal computer, PDA, a digital still camera, or a portable phone, that process various kinds of data such as image data, music data or ID data.

An interface signal terminal 310 includes a total of nine signal terminals, i.e., a CLK terminal used to transmit clocks from the host device to the memory card 300, a CMD terminal used to transmit commands and responses to the commands, DAT0, DAT1, DAT2, and DAT3 terminals used as input/output terminals for read/write data, a VDD terminal used to supply power, and two GND terminals for grounding.

These nine signal terminals are electrically connected to a host interface of the external host system, then the commands, addresses, and data are transmitted and received.

In the present embodiment, similar to the first embodiment, the semiconductor storage system which is capable of using efficiently a plurality of memory regions in which storable bits are mutually different is supplied for users.

Specifically, the semiconductor storage system is capable of using the 2 levels cell region and the 16 levels cell region efficiently by controlling the number of rewrites for the 2 levels cell region based on the guaranteed number of rewrites on the 2 levels cell region (100,000 times), and controlling the number of rewrites for the 16 levels cell region based on the guaranteed number of rewrites on the 16 levels cell region (1,000 times).

Moreover, the semiconductor storage system of the present embodiment may be applied to various type of flash memory card, such as a Mini SD card, a Micro SD card, a Smart Media, a Multi Media Card, a Compact Flash, or a USB (Universal Serial Bus) memory, and may be applied to SSD (Solid State Drive).

### Third Embodiment

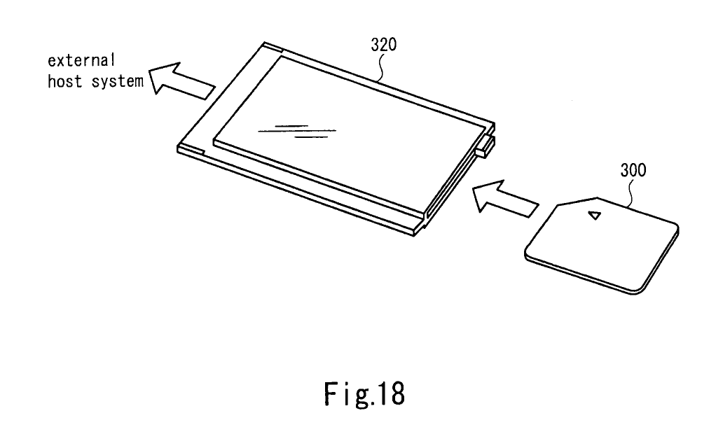

FIG. 18 illustrates a schematic view of a memory card holder 320 according to the third embodiment. The memory card 300 according to the second embodiment can be inserted into the memory card holder 320 shown in FIG. 18. The memory card holder 320 is connected to a external host system (not shown) and serves as an interface device between the memory card 300 and the external host system.

### Fourth Embodiment

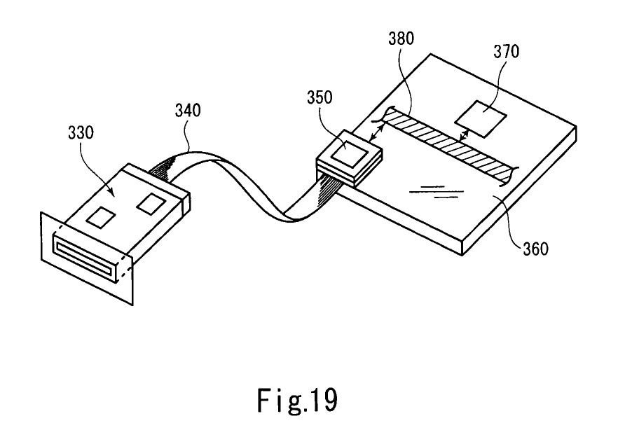

FIG. 19 illustrates a schematic view of a connector device 330 which can receive any one of the memory card 300 according to the second embodiment and the memory card holder 320 according to the third embodiment. The memory card 300 or the memory card holder 320 is electrically connected to the connector device 330 by being mounted on the connector device 330. The connector device 330 is connected to a board 360 via a connection wire 340 and an interface circuit 350. The board 360 has a CPU (Central Processing Unit) 370 and a bus 380 mounted thereon.

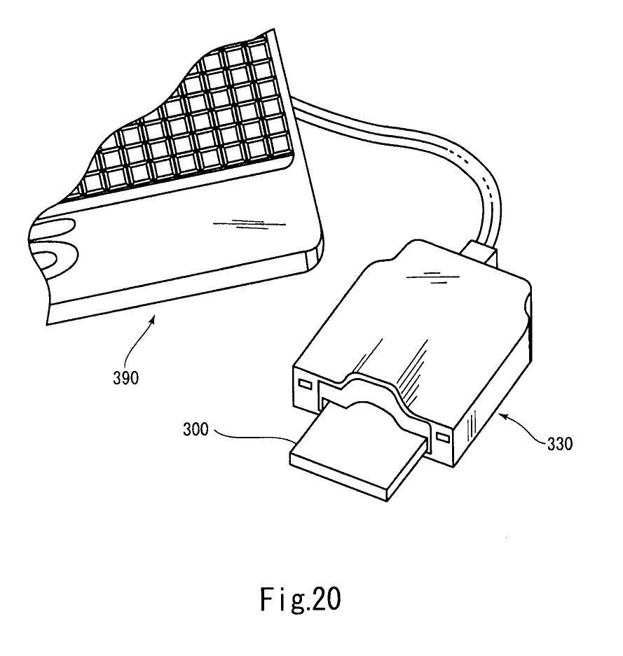

As shown in FIG. 20, the memory card 300 or the memory card holder 320 may be inserted into the connector device 330, and the connector device 330 may be connected to a personal computer via the connection wire 340.

What is claimed is:

1. A semiconductor storage system comprising:
a first memory region including at least one block constituted from a plurality of memory cells, the memory cell being capable of storing bits data, the block being a minimum unit which is capable of being independently erased;
a second memory region including at least one block constituted from a plurality of memory cells, the memory cell being capable of storing m (m>n: m is integer) bit data, the block being a minimum unit which is capable of being independently erased; and
a controller which controls a number of rewrites for the block in the first memory region not to be more than a first predetermined number of times, and controls a number of rewrites for the block in the second memory region not to be more than a second predetermined number of times.
